(19) United States
(12) Patent Application Publication
(10) Pub. No.: US 2026/0367430 A1
(43) Pub. Date: Nov. 19, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ming-Han Liao, Hsinchu (TW); Wen-Hao Cheng, Hsinchu (TW)

(21) Appl. No.: 19/328,609

(22) Filed: Sep. 15, 2025

Related U.S. Application Data
(60) Provisional application No. 63/804,721, filed on May 13, 2025.
(60) Provisional application No. 63/810,212, filed on May 22, 2025.

(51) Int. Cl. G02F 1/025; H10D 1/00; H10D 1/68

(52) U.S. Cl. CPC G02F 1/025; H10D 1/042; H10D 1/716

(57) ABSTRACT

Various embodiments of the present disclosure are directed to a wavelength tuner and method for forming the same. As an example, a waveguide is formed on a substrate. The substrate is patterned to form a trench, wherein the waveguide leads to the trench. A dielectric layer is deposited overlying the substrate and in the trench. Further, a conductive layer is deposited overlying the dielectric layer. The conductive layer and the dielectric layer are patterned to form a capacitor with a trench structure in the trench.

### REFERENCE TO RELATED APPLICATION

This application claims the benefit of U.S. Provisional Application No. 63/804,721, filed on May 13, 2025, and claims the benefit of U.S. Provisional Application No. 63/810,212, filed on May 22, 2025. The contents of both applications are incorporated herein by reference in their entirety.

### BACKGROUND

Silicon-photonics (SiPh) devices are silicon-based integrated-circuit (IC) devices that may be used for a variety of optical-related functions such as, for example, guiding, generating, manipulating, and detecting light. SiPh devices include, for example, waveguides, resonators, couplers, splitters, tuners, and rotators. A silicon-based tuner may be used for electric-to-optical (EO) signal conversion at a modulator, optical-to-electric (OE) signal conversion at a receiver, or the like.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of various features may be arbitrarily increased or reduced for clarity of discussion.

FIGS. 1A and 1B illustrate cross-sectional views of some embodiments of a wavelength tuner comprising a metal-oxide-semiconductor capacitor (MOSCAP).

FIG. 2 illustrates a top view of some embodiments of the wavelength tuner of FIGS. 1A and 1B.

FIGS. 3A and 3B illustrate cross-sectional views of some first embodiments of the wavelength tuner of FIG. 2.

FIGS. 4A and 4B illustrate cross-sectional views of some second embodiments of the wavelength tuner of FIG. 2.

FIGS. 5A and 5B illustrate cross-sectional views of some alternative embodiments of the wavelength tuner of FIGS. 1A and 1B in which the MOSCAP has fewer trench structures.

FIGS. 6A and 6B illustrate cross-sectional views of some alternative embodiments of the wavelength tuner of FIGS. 5A and 5B in which trench structures have different depths.

FIGS. 7A-7E illustrate cross-sectional views of some alternative embodiments of the wavelength tuner of FIGS. 1A and 1B in which trench structures have different configurations.

FIGS. 8A and 8B illustrate cross-sectional views of some alternative embodiments of the wavelength tuner of FIGS. 1A and 1B in which the wavelength tuner comprises a metal-insulator-metal (MIM) capacitor in place of a MOSCAP.

FIGS. 9A and 9B illustrate cross-sectional views of some alternative embodiments of the wavelength tuner of FIGS. 8A and 8B in which the wavelength tuner has increased depth and extends into a semiconductor substrate.

FIG. 10 illustrates a cross-sectional view of some alternative embodiments of the wavelength tuner of FIGS. 9A and 9B.

FIG. 11 illustrates a top view of some embodiments of the wavelength tuner of FIGS. 9A and 9B.

FIGS. 12A and 12B illustrate cross-sectional views of some embodiments of the wavelength tuner of FIG. 11.

FIGS. 13A and 13B illustrate cross-sectional views of some alternative embodiments of the wavelength tuner of FIGS. 8A and 8B in which the MIM capacitor has an additional capacitor electrode.

FIGS. 14A and 14B illustrate cross-sectional views of some alternative embodiments of the wavelength tuner of FIGS. 13A and 13B in which the wavelength tuner has increased depth and extends into a semiconductor substrate.

FIG. 15 illustrates a cross-sectional view of some alternative embodiments of the wavelength tuner of FIGS. 14A and 14B.

FIGS. 16A and 16B illustrate cross-sectional views of some alternative embodiments of the wavelength tuner of FIGS. 14A and 14B in which the wavelength tuner has additional trench structures.

FIG. 17 illustrates a cross-sectional view of some alternative embodiments of the wavelength tuner of FIGS. 16A and 16B.

FIG. 18 illustrates a cross-sectional view of some alternative embodiments of the wavelength tuner of FIGS. 1A and 1B in which the wavelength tuner further comprises a combination of the MOSCAP and a MIM capacitor.

FIG. 19 illustrates a cross-sectional view of some embodiments of an integrated circuit (IC) chip comprising a wavelength tuner according to aspects of the present disclosure.

FIG. 20 illustrates a top view of some embodiments of a ring modulator comprising a wavelength tuner according to aspects of the present disclosure.

FIG. 21 illustrates a top view of some embodiments of a Mach-Zehnder modulator (MZM) comprising a wavelength tuner according to aspects of the present disclosure.

FIG. 22 illustrates a top view of some alternative embodiments of the MZM of FIG. 21.

FIG. 23 illustrates a schematic view of some embodiments of a system comprising an optical transmitter and an optical receiver according to aspects of the present disclosure.

FIG. 24 illustrates a schematic view of some alternative embodiments of a transmit photonic integrated circuit (Tx PIC) of FIG. 23 in which a transmit bus wavelength is non-linear.

FIG. 25 illustrates a schematic view of some embodiments of an optical transmitter according to aspects of the present disclosure.

FIG. 26 illustrates a schematic view of some other embodiments of an optical transmitter according to aspects of the present disclosure.

FIGS. 27A and 27B to FIGS. 30A and 30B and FIGS. 31-38 illustrate a series of views of some embodiments of a method for forming a wavelength tuner comprising a capacitor according to aspects of the present disclosure.

FIG. 39 illustrates a block diagram of some embodiments of the method of FIGS. 27A and 27B to FIGS. 30A and 30B and FIGS. 31-38.

FIGS. 40A and 40B to FIGS. 46A and 46B and FIGS. 47-51 illustrate a series of cross-sectional views of some other embodiments of a method for forming a wavelength tuner comprising a capacitor according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

A silicon-based wavelength tuner may comprise a Metal-Oxide-Semiconductor Capacitor (MOSCAP). The MOSCAP comprises a doped semiconductor region of substrate, a dielectric layer overlying the doped semiconductor region, and an electrode overlying the dielectric layer. Such a wavelength tuner operates in an accumulation mode in which biasing the MOSCAP from the doped semiconductor region to the electrode causes free charge carriers (e.g., electrons or holes) to accumulate at the interface between the doped semiconductor region and the dielectric layer. By modulating the bias voltage, carrier concentration and hence refractive index of the doped semiconductor region are modulated, which enables wavelength tuning by passing a light beam through the doped semiconductor region.

A challenge with silicon-based tuners as above is that the effectiveness of the tuning mechanism is limited by capacitance density and such wavelength tuners may struggle to achieve high capacitance density. For example, the dielectric layer may be silicon dioxide with a flat lower surface and a flat upper surface. Silicon dioxide has low capacitance density relative to high-k dielectric materials. Further, the flat surfaces restrict the electric field distribution at the dielectric-semiconductor interface and therefore reduce the efficiency of carrier accumulation. The reduced efficiency leads to a small capacitance density.

Because capacitance density is proportional to wavelength shift per unit voltage (Δλ/ΔV), the small capacitance density leads to a small wavelength shift per unit voltage and hence high power consumption to achieve a large tuning range. Further, the flat surfaces restrict the contact area between the dielectric layer and the doped region, thereby leading to high contact resistance and hence high resistive-capacitive (RC) delay. This, in turn, reduces the speed of electric-to-optical (EO) or optical-to-electric (OE) signal conversion.

The present disclosure is directed to a wavelength tuner comprising a capacitor with a trench structure at least partially formed by a dielectric layer of the capacitor. The trench structure may, for example, extend into a doped semiconductor region of a substrate (e.g., a lower capacitor electrode of the capacitor) on which the capacitor is arranged or may extend into an upper capacitor electrode of the capacitor that overlies the dielectric layer.

The trench structure increases contact area between the dielectric layer and a lower or upper capacitor electrode and further increases capacitance density. The increased contact area reduces contact resistance and may hence reduce RC delay of the capacitor. This may, in turn, increase the speed of EO and OE signal conversions. Further, because capacitance density is proportional to wavelength shift per unit voltage (Δλ/ΔV), the increased capacitance density from the trench structure increases wavelength shift per unit voltage. As a result, a larger tuning range may be achieved for a given voltage and/or a lower voltage may be employed for a given wavelength shift to save power. The higher tuning range may, for example, enable reduced reliance on a heater or other high-power circuitry for wavelength tuning, thereby also reducing power consumption. Further, high-k dielectric materials may be used for the dielectric layer and/or additional electrode-dielectric pairs may be included in the MOSCAP to further increase capacitance density and hence wavelength shift per unit voltage.

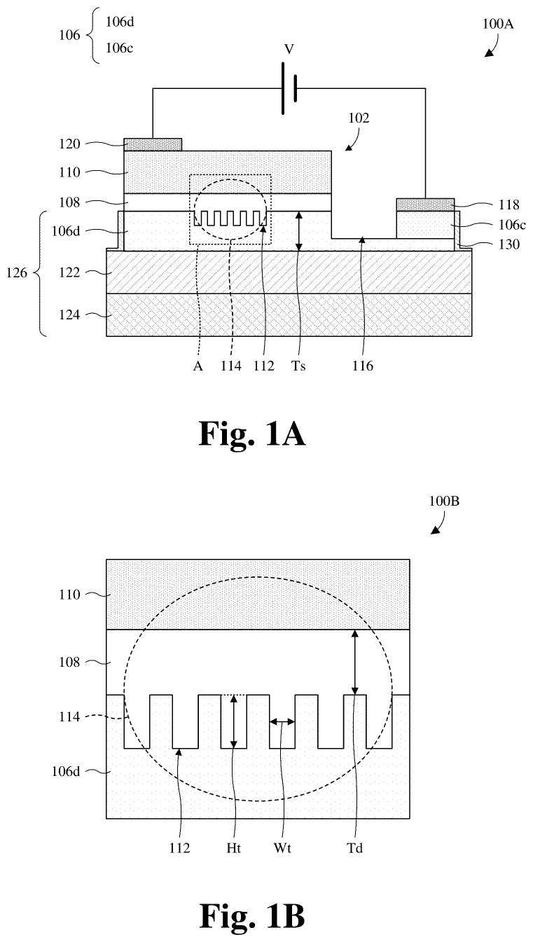

With reference to FIGS. 1A and 1B, cross-sectional views 100A, 100B of some embodiments of a wavelength tuner comprising a MOSCAP 102 are provided. The cross-sectional view 100A of FIG. 1A provides a wide field of view of the wavelength tuner, including the MOSCAP 102, whereas the cross-sectional view 100B of FIG. 1B provides a narrow field of view of the wavelength tuner that is focused within box A of FIG. 1A.

The MOSCAP 102 comprises a doped region 106d of a semiconductor layer 106, a capacitor dielectric layer 108 overlying the doped region 106d, and an upper capacitor electrode 110 overlying the capacitor dielectric layer 108. The capacitor dielectric layer 108 forms a plurality of trench structures 112 that protrude or otherwise extend from a bottom surface of the dielectric layer 108 into the doped region 106d, which forms a lower capacitor electrode of the MOSCAP 102. Because of the plurality of trench structures 112, the MOSCAP 102 may be characterized as having a surface trenched structure.

During use of the wavelength tuner, a light beam 114 is passed through the MOSCAP 102 while the MOSCAP 102 is biased with a voltage V applied from the doped region 106d to the upper capacitor electrode 110. The light beam 114 may, for example, be passed through the MOSCAP 102 by a waveguide or the like, whereby reference number 114 may also represent the waveguide or the like. The voltage V causes the accumulation of free charge carriers (e.g., electrons or holes) at the interface between the doped region 106d and the capacitor dielectric layer 108. By modulating the voltage V, carrier concentration and hence refractive index of the doped region 106d are modulated to wavelength tune the light beam 114.

The tuning efficiency is proportional to capacitance of the MOSCAP 102. For example, the relationship between wavelength shift per unit voltage and capacitance may be represented as:

$$\frac{Δλ}{ΔV} ∝ \frac{α C}{{V}_{m o d e}} ,$$

wherein Δλ is wavelength shift, ΔV is change in voltage, α is overlap between the MOSCAP 102 and the light beam 114 (also known as the optical mode), C is capacitance, and V_{mode} is the optical mode volume. Further, as confirmed experimentally, capacitance density is proportional to tuning efficiency. Capacitors that had higher capacitance densities (e.g., in terms of microfarads per centimeter squared

$$( \frac{μF}{{cm}^{2}} ) )$$

showed higher tuning efficiency (e.g., in terms of picometers per Volt (pm/V)).

Because of the plurality of trench structures 112, capacitance density of the MOSCAP 102 is increased at the light beam 114 and hence tuning efficiency (e.g., wavelength shift per unit voltage) is increased. As a result, a larger tuning range may be achieved for a given voltage and/or a lower voltage may be employed for a given wavelength shift to save power. Further, the higher tuning range may, for example, enable reduced reliance on a heater or other high-power circuitry for wavelength tuning, thereby also reducing power consumption.

Because of the plurality of trench structures 112, contact area between the capacitor dielectric layer 108 and the doped region 106d is increased. The increased contact area reduces contact resistance and may hence reduce RC delay of the MOSCAP 102 despite the increase in capacitance. This may, in turn, increase the speed of EO and OE signal conversions.

In some embodiments, the capacitor dielectric layer 108 is or comprises a high-k dielectric material. The high-k dielectric material may, for example, be a material with a dielectric constant greater than that of silicon dioxide or greater than about 3.9. Because of the high-k dielectric material, capacitance density of the MOSCAP 102 may be further increased. This, in turn, further increases tuning efficiency

$$( e . g . , \frac{Δλ}{ΔV} ) .$$

In some embodiments, the capacitor dielectric layer 108 additionally or alternatively comprises silicon oxide and/or the like. Further, in some embodiments, the capacitor dielectric layer 108 is an electro-optic material.

The high-k dielectric material may, for example, be or comprise aluminum oxide (e.g., Al₂O₃), hafnium oxide (e.g., HfO₂), lanthanum oxide (e.g., La₂O₃), yttrium oxide (e.g., Y₂O₃), lanthanum nitride (e.g., La₂N₃), tantalum oxide (e.g., Ta₂O₅), titanium oxide (e.g., TiO₂), zirconium oxide (e.g., ZrO₂), zinc oxide (e.g., ZnO), barium titanium oxide (e.g., BaTiO₃), some other suitable material, or any combination of the foregoing. Further, the high-k dielectric material may, for example, additionally or alternatively comprise Group II elements, Group VI elements, Lanthanides elements, or some other suitable elements.

Focusing on FIG. 1B, the plurality of trench structures 112 have individual widths Wt and individual heights Ht (or depths). In some embodiments, the individual widths Wt are the same or about the same as each other, and/or the individual heights Ht are the same or about the same as each other. Further, in some embodiments, the individual widths Wt are about 20 nanometers to 20 micrometers, about 20 nanometers to 10 micrometers, about 10 micrometers to 20 micrometers, or some other suitable value. Further, in some embodiments, the individual heights Ht are about 20 nanometers to 20 micrometers, about 20 nanometers to 10 micrometers, about 10 micrometers to 20 micrometers, or some other suitable value.

In some embodiments, the plurality of trench structures 112 have individual aspect ratios of height to width (e.g., Ht/Wt) that are about 1-20, about 1-10, about 10-20, or some other suitable value. If the aspect ratio is too large (e.g., more than about 20), process challenges may arise and manufacturing yields may be low. If the aspect ratio is too small (e.g., less than about one), any gain in capacitance density may be minimal and outweighed by increased manufacturing costs from forming the plurality of trench structures 112.

In some embodiments, the capacitor dielectric layer 108 has a thickness Td that is about 10 nanometers to 200 nanometers, about 10-100 nanometers, about 100-200 nanometers, or some other suitable value. If the thickness Td is too large (e.g., greater than about 200 nanometers), capacitance density may be low and hence tuning efficiency may be low. If the thickness Td is too small (e.g., less than 10 nanometers), the MOSCAP 102 may have a high leakage current and a low breakdown voltage.

Focusing on both FIGS. 1A and 1B, the capacitor dielectric layer 108, the upper capacitor electrode 110, and a portion of the doped region 106d are stacked to form a capacitor stack, which is laterally separated from a contact region 106c of the semiconductor layer 106 by a trench 116 extending partially through a thickness Ts of the semiconductor layer 106. The thickness Ts has a first non-zero value at the capacitor stack and the contact region 106c and has a second non-zero value less than the first non-zero value at the trench 116.

In some embodiments, the doped region 106d, the capacitor dielectric layer 108, and the upper capacitor electrode 110 have first individual sidewalls that are edge to edge to form a first common sidewall facing the contact region 106c. Further, in some embodiments, the doped region 106d, the capacitor dielectric layer 108, and the upper capacitor electrode 110 have second individual sidewalls that are edge to edge to form a second common sidewall, which faces away from the contact region 106c with a greater height than the first common sidewall.

The contact region 106c corresponds to a doped region of the semiconductor layer 106 that overlies and extends from the doped region 106d. Further, the contact region 106c has the same doping type as, but a greater doping concentration than, the doped region 106d. As such, the contact region 106c is electrically coupled to the doped region 106d. In some embodiments, the doped region 106d and the contact region 106c have first individual sidewalls that are edge to edge to form common sidewall facing away from the capacitor stack.

The upper capacitor electrode 110 may, for example, be or comprise metal, a metal-containing material, a semiconductor material, some other suitable conductive material, or any combination of the foregoing. Hence, the upper capacitor electrode 110 is conductive, but may or may not be semiconductive. The metal or metal-containing material may, for example, be or comprise titanium nitride (e.g., TiN), aluminum (e.g., Al), tantalum nitride (e.g., TaN), tungsten (e.g., W), copper (e.g., Cu), ruthenium (e.g., Ru), some other suitable conductive materials, or any combination of the foregoing. The semiconductor material may, for example, be or comprise doped polysilicon and/or some other suitable material.

To the extent that the upper capacitor electrode 110 is or comprises a semiconductor material, the semiconductor material has a different conductivity type (e.g., doping type) as the doped region 106d. In some embodiments, the doped region 106d is P-type, whereas the upper capacitor electrode 110 is N-type, or vice versa. Further, in some embodiments, the doped region 106d and the upper capacitor electrode 110 are or otherwise comprise a common semiconductor material but have different crystallinities. For example, the doped region 106d may be or comprise P-type monocrystalline silicon, whereas the upper capacitor electrode 110 may be or comprise N-type polycrystalline silicon (e.g., polysilicon).

In some embodiments, a doping concentration of the doped region 106d is about 10¹⁹-10²¹ atoms per cubic centimeter (cm⁻³) or some other suitable doping concentration. Further, in some embodiments, to the extent that the upper capacitor electrode 110 is a doped semiconductor material, a doping concentration of the upper capacitor electrode 110 is about 10¹⁹-10²¹ atoms per cubic centimeter (cm⁻³) or some other suitable doping concentration.

A lower conductive contact 118 is atop the contact region 106c, and an upper conductive contact 120 is atop the upper capacitor electrode 110. In some embodiments, the upper conductive contact 120 has a sidewall overlying and edge to edge with a sidewall of the upper capacitor electrode 110 to extend the first common sidewall facing away from the conductive contact. In some embodiments, the lower conductive contact 118 and the contact region 106c share a common width with individual sidewalls that are edge to edge. During use of the MOSCAP 102 as described above, the voltage V is applied to the MOSCAP 102 via the lower and upper conductive contacts 118, 120 and the contact region 106c.

In some embodiments, the lower conductive contact 118 is or comprises metal, some other suitable conductive material, or any combination of the foregoing, and/or the upper conductive contact 120 is or comprises metal, some other suitable conductive material, or any combination of the foregoing. The lower conductive contact 118 and the upper conductive contact 120 may, for example, be the same material or different materials.

An insulator layer 122 underlies the semiconductor layer 106 and a handle substrate 124 underlies the insulator layer 122. In some embodiments, the semiconductor layer 106, the insulator layer 122, and the handle substrate 124 form a semiconductor-on-insulator (SOI) substrate 126. Further, in some embodiments, the semiconductor layer 106 may also be referred to as a device layer, an active layer, or the like.

In some embodiments, the semiconductor layer 106 is or comprises monocrystalline silicon and/or some other suitable semiconductor material. In some embodiments, the insulator layer 122 is or comprises silicon oxide and/or some other suitable dielectric material. In some embodiments, the handle substrate 124 is or comprises monocrystalline silicon and/or some other suitable semiconductor material. In some embodiments, the semiconductor layer 106 and the handle substrate 124 share a common semiconductor material (e.g., silicon or the like).

In some embodiments, a cladding layer 130 overlies the insulator layer 122 on sidewalls of the semiconductor layer 106. The cladding layer 130 aids in confining light within a core structure of a waveguide (not visible in FIGS. 1A and 1B) by promoting total internal reflection at the interface between the cladding layer 130 and the core structure. For example, the cladding layer 130 may be or comprise a material having a lower refractive index compared to a material of the core structure to promote total internal reflection.

In some embodiments, the cladding layer 130 also aids in confining light within the doped region 106d by total internal reflection. Further, in some embodiments, the cladding layer 130 serves as upper cladding layer for the core structure and/or the doped region 106d while the insulator layer 122 serves as lower cladding. The cladding layer 130 may be a solid, as illustrated, or may alternatively be an air gap or some other suitable type of cladding. Further, the core/cladding materials may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or some other suitable combination of core/cladding materials.

As will be better seen hereafter, the wavelength tuner finds applicability to EO signal conversion at a modulator, OE signal conversion at a receiver, or the like. Such a modulator and/or such a receiver are used in communications, computing, sensing, and more and may, for example, be employed for Wavelength Division Multiplexing (WDM). WDM depends on precise wavelength (λ) control with high tunability for wavelength (λ)-alignment (between laser-source, transmitter, and receiver) to ensure high data communication quality with minimum error-rate.

While the wavelength tuner is described as having the MOSCAP 102, the MOSCAP 102 may be replaced with a Metal-Insulator-Metal (MIM) capacitor or some other suitable type of capacitor in alternative embodiments. Such a MIM capacitor may have two, three, four, or more dielectric-electrode pairs stacked upon each other. Hence, the present disclosure is more generally directed to a wavelength tuner with a capacitor having a trench structure.

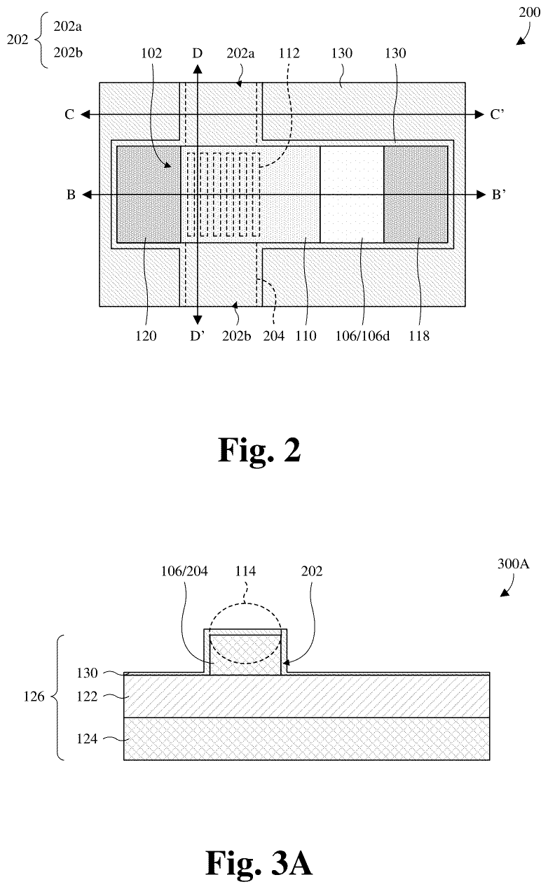

With reference to FIG. 2, a top view 200 of some embodiments of the wavelength tuner of FIGS. 1A and 1B is provided. The cross-sectional view 100A of FIG. 1A may, for example, be taken along line B-B′ in FIG. 2.

A waveguide 202 carries the light beam 114 in FIGS. 1A and 1B and guides the light beam 114 through the MOSCAP 102 at the plurality of trench structures 112. Hence, the waveguide 202 may be regarded as extending to/from the plurality of trench structures 112. The waveguide 202 comprises a first segment 202a configured to lead light to the MOSCAP 102 and comprises a second segment 202b configured to lead light away from the MOSCAP 102 after it passes through the MOSCAP 102. The waveguide 202 may, for example, be a strip waveguide, a slot waveguide, a rib waveguide, or some other suitable type of waveguide.

The waveguide 202 comprises a core structure 204 for carrying light, as well as a cladding around the core structure 204 for confining light in the core structure 204. The outline of the core structure 204 is visible but is not directly seen because of the cladding layer 130, which covers the core structure 204.

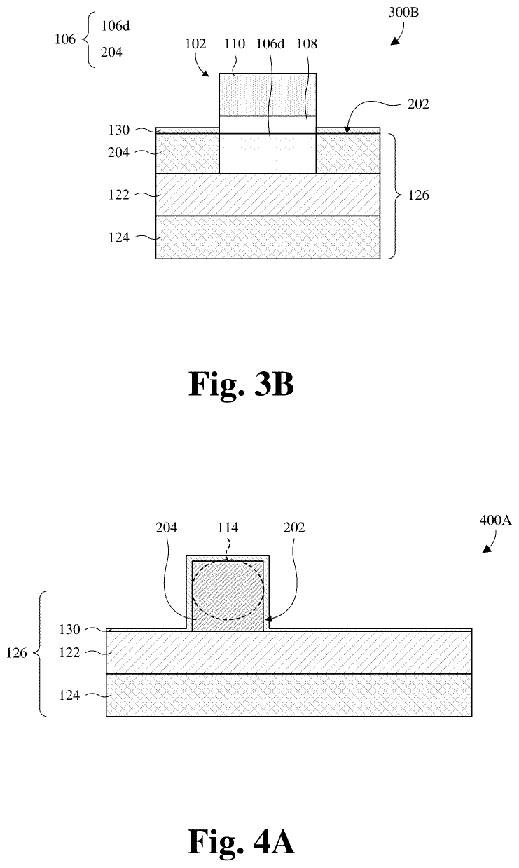

With reference to FIGS. 3A and 3B, cross-sectional views 300A, 300B of some first embodiments of the wavelength tuner of FIG. 2 are provided. The cross-sectional view 300A of FIG. 3A may, for example, be taken along line C-C′ and the cross-sectional view 300B of FIG. 3B may, for example, be taken along line D-D′.

The core structure 204 is formed in the semiconductor layer 106 into which the plurality of trench structures 112 of the MOSCAP 102 extend. As a result, the core structure 204 is the same semiconductor material as the doped region 106d of the MOSCAP 102. However, in contrast with the doped region 106d, the core structure 204 has a lesser doping concentration than the doped region 106d. Dopants scatter light and degrade waveguide efficiency. In some embodiments, the core structure 204 is undoped. In other embodiments, the core structure 204 is lightly doped with a doping concentration less than the doped region 106d.

The cladding is formed by the insulator layer 122 and the cladding layer 130. The cladding layer 130 overlies and conforms to the core structure 204. The cladding layer 130 is on a top surface of the core structure 204 and sidewalls of the core structure 204, whereby the cladding layer 130 forms upper cladding of the waveguide 202. The insulator layer 122 is on a bottom surface of the core structure 204, whereby the insulator layer 122 forms lower cladding of the waveguide 202. The cladding layer 130 and the insulator layer 122 may be the same material or different materials.

As above, the cladding may be a solid, an air gap, or some other suitable type of cladding. Further, the core/cladding materials may, for example, be or comprise silicon nitride/silicon oxide, lithium niobate/silicon oxide, silicon/titanium oxide, titanium oxide/silicon oxide, or some other suitable combination of core/cladding materials.

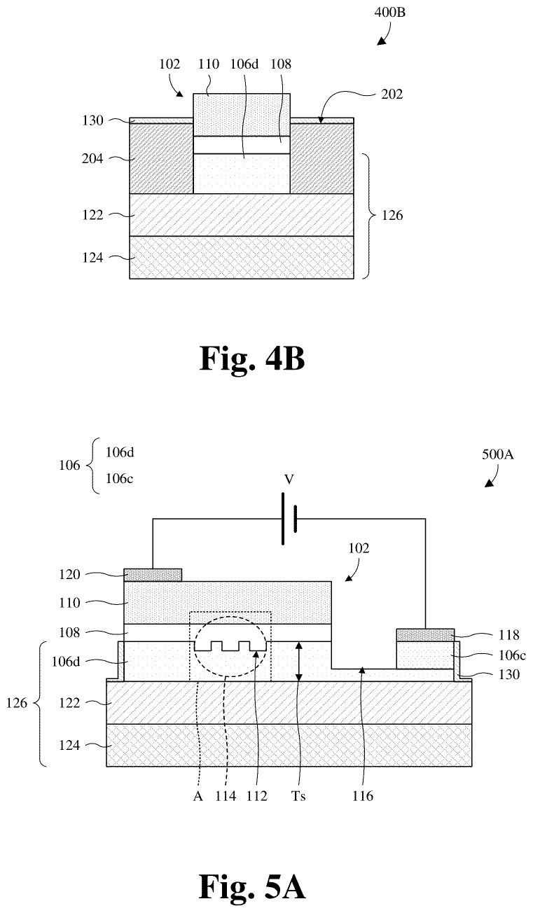

With reference to FIGS. 4A and 4B, cross-sectional views 400A, 400B of some second embodiments of the wavelength tuner of FIG. 2 are provided. The cross-sectional view 400A of FIG. 4A may, for example, be taken along line C-C′ and the cross-sectional view 400B of FIG. 4B may, for example, be taken along line D-D′. In contrast with the first embodiments of FIGS. 3A and 3B, the core structure 204 is independent of the semiconductor layer 106. For example, the core structure 204 is a different material than the semiconductor layer 106. Hence, a hashing of the core structure 204 has been changed compared to in FIG. 3A.

In some embodiments, the semiconductor layer 106 is or comprises silicon, whereas the core structure 204 is or comprises silicon nitride, titanium oxide, lithium niobate, or some other suitable material. In some embodiments, the core structure 204 is formed on the insulator layer 122, laterally next to the doped region 106d of the semiconductor layer 106. In other embodiments, the core structure 204 is formed atop the semiconductor layer 106, which may be thinned at the core structure 204. In some embodiments, the core structure 204 has a height different than a height of the semiconductor layer 106. For example, the height of the core structure 204 may be greater than the height of the semiconductor layer 106.

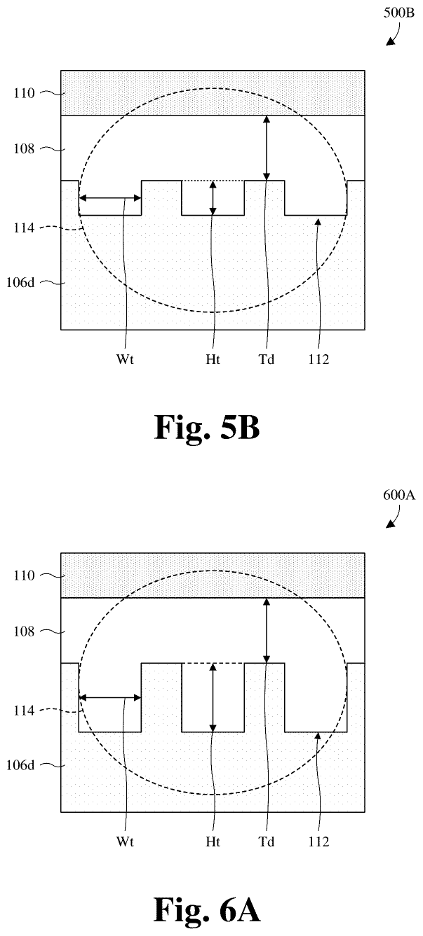

With reference to FIGS. 5A and 5B, cross-sectional views 500A, 500B of some alternative embodiments of the wavelength tuner of FIGS. 1A and 1B are provided in which the MOSCAP 102 has fewer trench structures. For example, in contrast with FIGS. 1A and 1B that have six trench structures, FIGS. 5A and 5B have three trench structures. In alternative embodiments, the wavelength tuner has more or less trench structures.

In addition to having fewer trench structures, the plurality of trench structures 112 are shallow in the embodiments at FIGS. 5A and 5B. For example, the plurality of trench structures 112 have individual aspect ratios of height to width (e.g., Ht/Wt) that are about 1-5, about 1-3, about 3-5, or some other suitable value. As above, if aspect ratio is too small (e.g., less than about one), any gain in capacitance density may be minimal and outweighed by increased manufacturing costs from forming the plurality of trench structures 112.

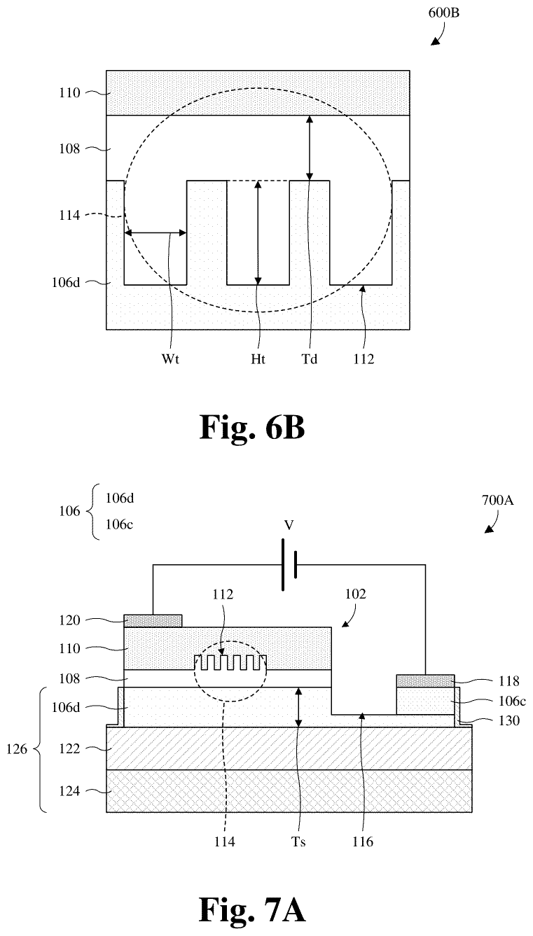

With reference to FIGS. 6A and 6B, cross-sectional views 600A, 600B of some alternative embodiments of the wavelength tuner of FIGS. 5A and 5B are provided in which the plurality of trench structures 112 have different depths.

In FIG. 6A, the plurality of trench structures 112 are medium depth trench structures. For example, the plurality of trench structures 112 have individual aspect ratios of height to width (e.g., Ht/Wt) that are about 5-10, about 5-7.5, about 7.5 to 10, or some other suitable value. In FIG. 6B, the plurality of trench structures 112 are deep trench structures. For example, the individual aspect ratios are about 10-20, about 10-15, about 15-20, or some other suitable value. If an aspect ratio of a trench structure is too large (e.g., more than about 20), process challenges may arise and manufacturing yields may be low.

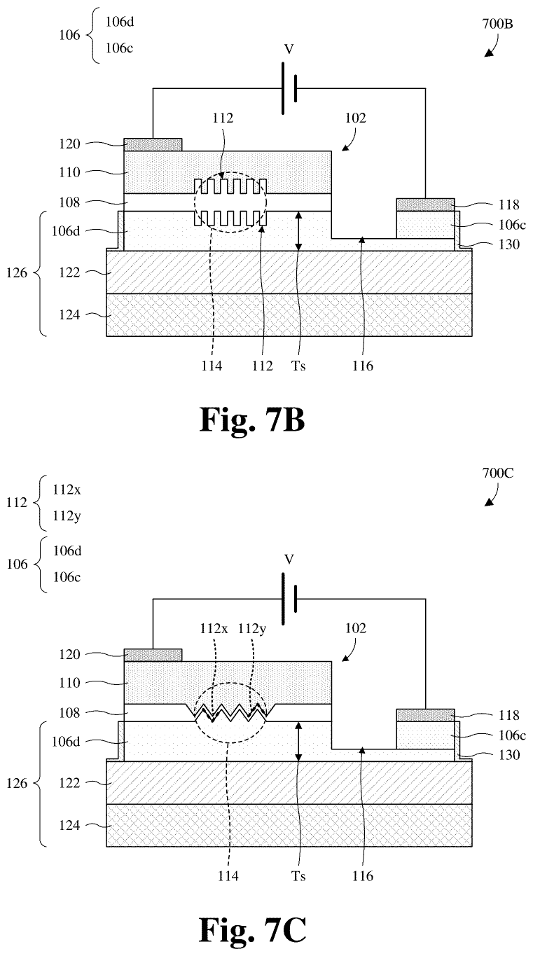

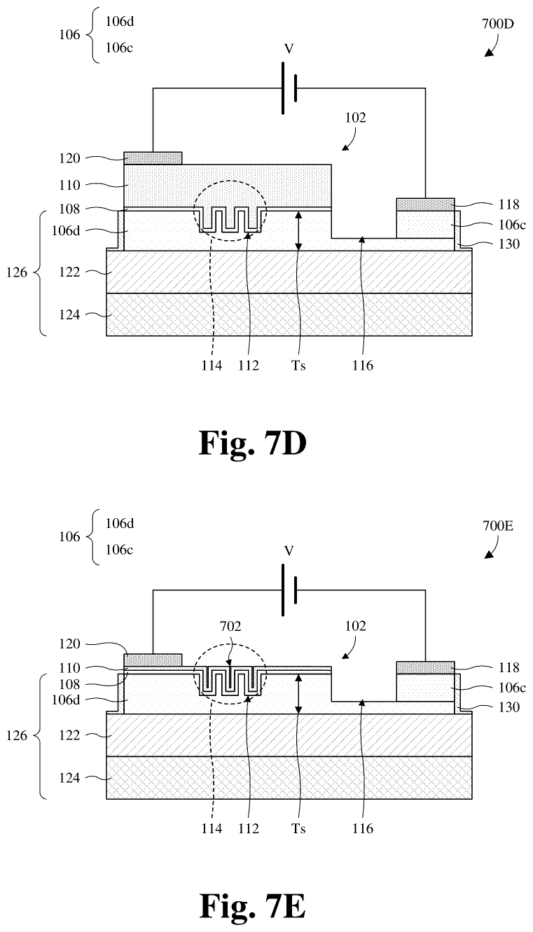

With reference to FIGS. 7A-7E, cross-sectional views 700A-700E of some alternative embodiments of the wavelength tuner of FIGS. 1A and 1B are provided in which the plurality of trench structures 112 have different configurations.

In FIG. 7A, the plurality of trench structures 112 protrude from a top of the capacitor dielectric layer 108 rather than a bottom of the capacitor dielectric layer 108. As such, the plurality of trench structures 112 protrude into the upper capacitor electrode 110.

In FIG. 7B, the plurality of trench structures 112 protrude from both a top of the capacitor dielectric layer 108 and from a bottom of the capacitor dielectric layer 108. Trench structures at the top of the capacitor dielectric layer 108 protrude into the upper capacitor electrode 110, whereas trench structures at the bottom of the capacitor dielectric layer 108 protrude into the doped region 106d. In some embodiments, the number of trench structures at the top of the capacitor dielectric layer 108 is the same as the number of trench structures at the bottom of the capacitor dielectric layer 108. In other embodiments, the numbers are different.

In FIG. 7C, a portion of the capacitor dielectric layer 108 through which the light beam 114 is configured to pass has a reduced thickness compared to surrounding portions of the capacitor dielectric layer 108. Further, this portion has an upper surface with an upper saw-toothed profile and a lower surface with a lower saw-toothed profile complementary to the upper saw-toothed profile. The upper capacitor electrode 110 has a lower surface conforming to the upper saw-toothed profile of the capacitor dielectric layer 108, and the doped region 106d has an upper surface conforming to the lower saw-toothed profile of the dielectric layer.

The capacitor dielectric layer 108, the upper capacitor electrode 110, and the doped region 106d (e.g., lower capacitor electrode) form the plurality of trench structures 112 with tooth-shaped profiles corresponding to the upper and lower saw-toothed profiles. The capacitor dielectric layer 108 and the upper capacitor electrode 110 form tooth-shaped trench structures 112x extending downward into the doped region 106d, whereas the capacitor dielectric layer 108 and the doped region 106d form tooth-shaped trench structures 112y extending upward into the upper capacitor electrode 110. A tooth-shaped profile may, for example, correspond to a triangular profile culminating in a point or some other suitable profile.

In FIG. 7D, the upper capacitor electrode 110 has a plurality of protrusions protruding into the doped region 106d. Further, the capacitor dielectric layer 108 conforms to these protrusions to separate the protrusions from the doped region 106d. The plurality of protrusions and a portion of the capacitor dielectric layer 108 lining the protrusions form the plurality of trench structures 112.

In FIG. 7E, the upper capacitor electrode 110 and the capacitor dielectric layer 108 conform to a plurality of trenches in the doped region 106d to form the plurality of trench structures 112. Further, a plurality of gaps 702 remain in the plurality of trenches, which is to be contrasted with FIG. 7D where the plurality of trench structures 112 completely fill the plurality of trenches.

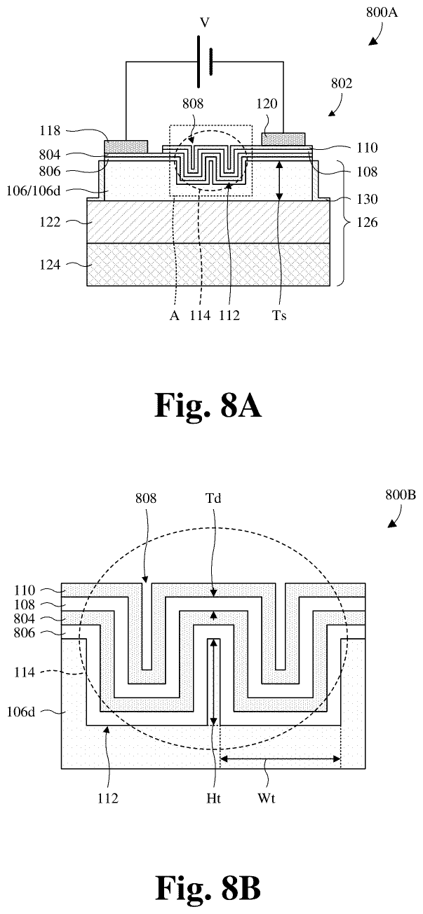

With reference to FIGS. 8A and 8B, cross-sectional views 800A, 800B of some alternative embodiments of the wavelength tuner of FIGS. 1A and 1B are provided in which the wavelength tuner comprises a MIM capacitor 802 in place of the MOSCAP 102. The cross-sectional view 800A of FIG. 8A provides a wide field of view of the wavelength tuner, including the MOSCAP 102, whereas the cross-sectional view 800B of FIG. 8B provides a narrow field of view of the wavelength tuner that is focused within box A of FIG. 8A.

Instead of using the doped region 106d as a lower capacitor electrode, the MIM capacitor 802 includes a lower capacitor electrode 804 independent of the doped region 106d and separated from the doped region 106d by a buffer dielectric layer 806. The buffer dielectric layer 806 may, for example, be or comprise silicon oxide and/or some other suitable dielectric.

The lower capacitor electrode 804 may, for example, be or comprise metal, a metal-containing material, some other suitable conductive material, or any combination of the foregoing. The lower capacitor electrode 804 may, for example, be the same material as or a different material than the upper capacitor electrode 110. The metal or metal-containing material may, for example, be or comprise titanium nitride (e.g., TiN), aluminum (e.g., Al), tantalum nitride (e.g., TaN), tungsten (e.g., W), copper (e.g., Cu), ruthenium (e.g., Ru), some other suitable conductive material, or any combination of the foregoing.

Because the doped region 106d is not employed as a lower capacitor electrode, the contact region 106c is omitted and the lower conductive contact 118 is moved to the lower capacitor electrode 804. Further, doping at the doped region 106d may be omitted and replaced with an undoped or intrinsic semiconductor region in alternative embodiments.

The lower capacitor electrode 804, the capacitor dielectric layer 108, the upper capacitor electrode 110, and the buffer dielectric layer 806 are stacked and conform to a plurality of trenches in the doped region 106d to form the plurality of trench structures 112. Further, a plurality of gaps 808 remain in the plurality of trenches. While two trench structures are shown, more or less trench structures are amenable in alternative embodiments. Further, while the capacitor is different in FIGS. 8A and 8B than in FIGS. 1A and 1B, the top view of FIG. 2 still applies with the waveguide 202 guiding light to the MIM capacitor 802.

During use of the wavelength tuner, a light beam 114 is passed through the MIM capacitor 802 while the MIM capacitor 802 is biased with a voltage V applied from the lower capacitor electrode 804 to the upper capacitor electrode 110. The light beam 114 may, for example, be passed through the MIM capacitor 802 by a waveguide or the like. The voltage V controls an electric field along the path of the light beam 114, which controls a refractive index along the path. Therefore, by modulating the voltage V, refractive index along the path of the light beam 114 is modulated to wavelength tune of the light beam 114. In some embodiments, the light beam 114 passes through the MIM capacitor 802 in the capacitor dielectric layer 108 and/or tuning is facilitated by the capacitor dielectric layer 108 being an electro-optic material.

As with the MOSCAP 102, the tuning efficiency is proportional to capacitance density. Because of the plurality of trench structures 112, capacitance density of the MIM capacitor 802 is increased at the light beam 114 and hence tuning efficiency (e.g., wavelength shift per unit voltage) is increased. As a result, a larger tuning range may be achieved for a given voltage and/or a lower voltage may be employed for a given wavelength shift to save power. Further, the higher tuning range may, for example, enable reduced reliance on a heater or other high-power circuitry for wavelength tuning, thereby also reducing power consumption.

Because of the plurality of trench structures 112, contact area between the capacitor dielectric layer 108 and the lower capacitor electrode 804 and contact between the capacitor dielectric layer 108 and the upper capacitor electrode 110 are increased. The increased contact areas reduce contact resistance and may hence reduce RC delay of the MIM capacitor 802. This may, in turn, increase the speed of EO and OE signal conversions.

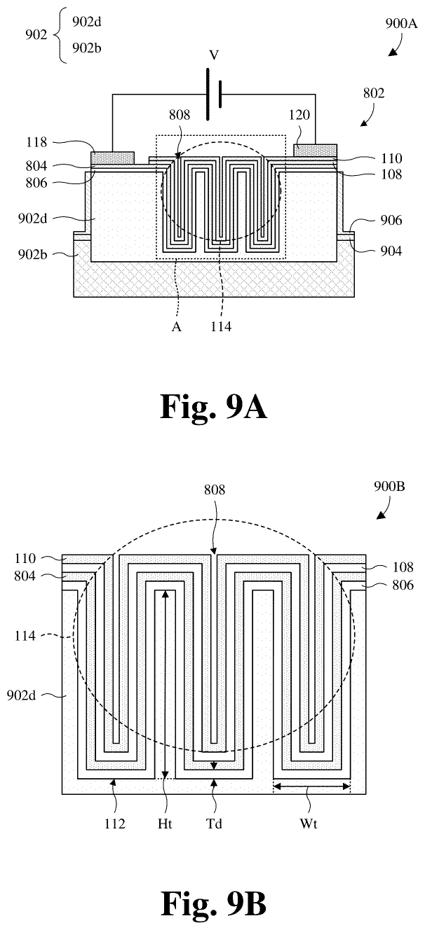

With reference to FIGS. 9A and 9B, cross-sectional views 900A, 900B of some alternative embodiments of the wavelength tuner of FIGS. 8A and 8B are provided in which the wavelength tuner has increased depth and extends into a semiconductor substrate 902 rather than a SOI substrate 126. Further, the MIM capacitor 802 has three trench structures rather than the two trench structures shown in FIGS. 8A and 8B.

The plurality of trench structures 112 overlie and extend into a doped region 902d of the semiconductor substrate 902, which overlies and is inset into a bulk region 902b of the semiconductor substrate 902. The doped region 902d may, for example, be doped with N-type or P-type dopants and/or may, for example, have an elevated doping concentration relative to the bulk region 902b. The bulk region 902b may, for example, be undoped or intrinsic or otherwise lightly doped relative to the doped region 902d.

By forming the plurality of trench structures 112 in the semiconductor substrate 902 rather than the semiconductor layer 106 of a SOI substrate 126, the plurality of trench structures 112 can extend deeper than they would otherwise be able to. Hence, capacitance density may be further increased for enhanced tuning efficiency.

In some embodiments, the MIM capacitor 802 has a capacitance density of about 500 femtofarads per micrometer squared (fF/um²)), about 200-400 fF/um², about 400-600 fF/um², about 600-800 fF/um², or some other suitable value. Further, in some embodiments, the MIM capacitor 802 has tuning efficiency of about 8900 picometers per Volt (pm/V), about 7000-8500 pm/V, 8500-9500 pm/V, about 9500-11000 pm/V, or some other suitable value.

The MIM capacitor 802 is at a mesa formed in the semiconductor substrate 902, whereby the semiconductor substrate 902 has a reduced thickness outside the area at which the MIM capacitor 802 is. In some embodiments, a lower cladding layer 904 and an upper cladding layer 906 are stacked on the semiconductor substrate 902 outside this area. The lower cladding layer 904 is generally localized to horizontally extending surfaces, whereas the upper cladding layer 906 is on horizontally extending surfaces, as well as sidewalls of the mesa.

As with the cladding layer 130 in FIGS. 1A and 1B, the lower and upper cladding layers 904, 906 aid in confining light within a core structure of a waveguide (not visible in FIGS. 9A and 9B) by promoting total internal reflection at the interfaces between the lower and upper cladding layers 904, 906 and the core structure. For example, the lower and upper cladding layers 904, 906 may be or comprise a material having a lower refractive index compared to a material of the core structure to promote total internal reflection.

In some embodiments, the lower and upper cladding layers 904, 906 also aid in confining light within the doped region 106d by total internal reflection. The cladding layer 130 may be a solid, as illustrated, or may alternatively be an air gap or some other suitable type of cladding. Further, the core/cladding materials may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or some other suitable combination of core/cladding materials.

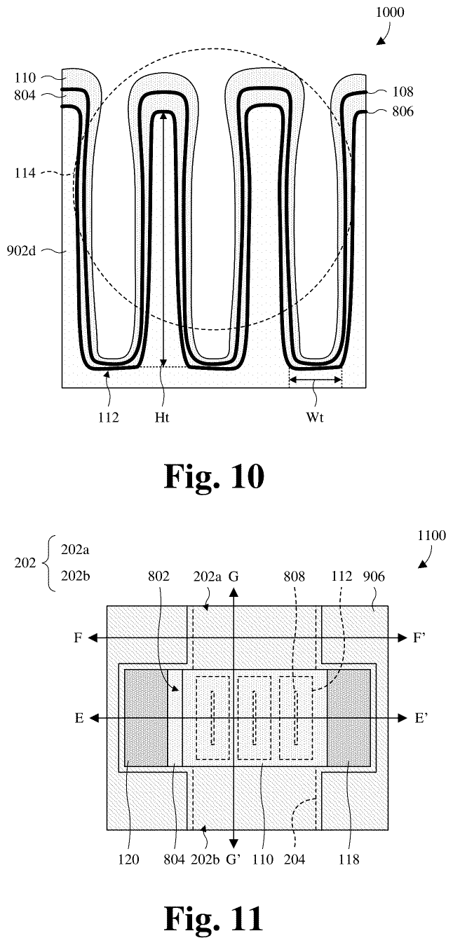

With reference to FIG. 10, a cross-sectional view 1000 of some alternative embodiments of the wavelength tuner of FIGS. 9A and 9B is provided in which the surfaces of the MIM capacitor 802 are less rectilinear. Further, for ease of illustration, the capacitor dielectric layer 108 and the buffer dielectric layer 806 are shown as thick, black lines.

With reference to FIG. 11, a top view 1100 of some embodiments of the wavelength tuner of FIGS. 9A and 9B is provided. The cross-sectional view 900A of FIG. 9A may, for example, be taken along line E-E′ in FIG. 11. A waveguide 202 carries the light beam 114 in FIGS. 9A and 9B and guides the light beam 114 through the MIM capacitor 802 at the plurality of trench structures 112. The waveguide 202 comprises a core structure 204 for carrying light, as well as a cladding around the core structure 204. The outline of the core structure 204 is visible but is not directly seen because of coverage by the upper cladding layer 906.

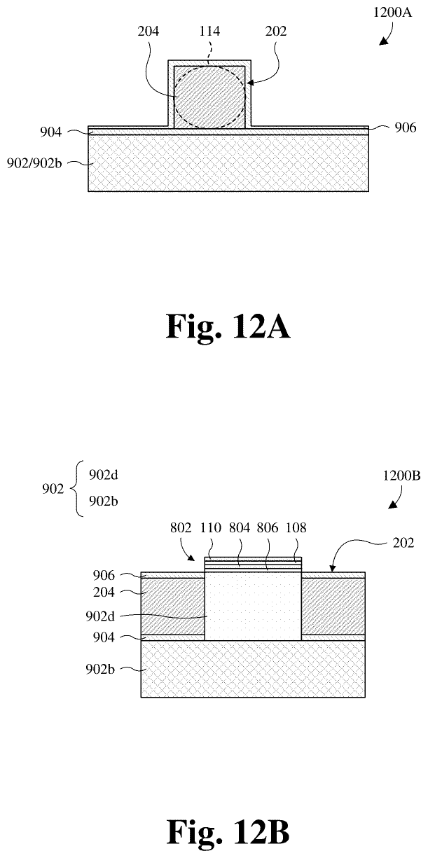

With reference to FIGS. 12A and 12B, cross-sectional views 1200A, 1200B of some embodiments of the wavelength tuner of FIG. 11 are provided. The cross-sectional view 1200A of FIG. 12A may, for example, be taken along line F-F′ and the cross-sectional view 1200B of FIG. 12B may, for example, be taken along line G-G′. The waveguide 202 comprises the core structure 204 and a cladding surrounding the core structure 204.

The core structure 204 is independent of the semiconductor layer 106. For example, the core structure 204 is a different material than the semiconductor layer 106. The cladding is formed by the lower cladding layer 904 and the upper cladding layer 906. The lower cladding layer 904 underlies the core structure 204 and lines a bottom surface of the core structure 204. The upper cladding layer 906 overlies and conforms to the core structure 204 to line a top surface of the core structure 204 and sidewalls of the core structure 204. The lower and upper cladding layers 904, 906 may, for example, be the same material or different materials.

As above, the cladding may be a solid, an air gap, or some other suitable type of cladding. Further, the core/cladding materials may, for example, be or comprise silicon nitride/silicon oxide, lithium niobate/silicon oxide, silicon/titanium oxide, titanium oxide/silicon oxide, or some other suitable combination of core/cladding materials.

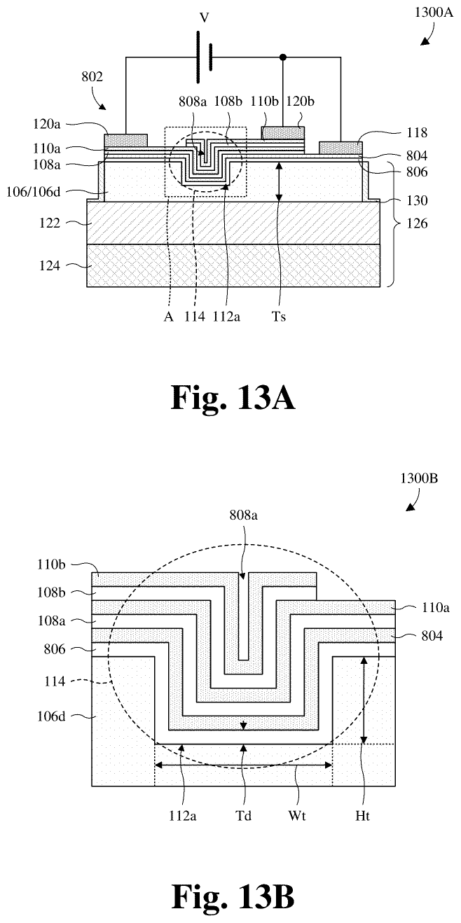

With reference to FIGS. 13A and 13B, cross-sectional views 1300A, 1300B of some alternative embodiments of the wavelength tuner of FIGS. 8A and 8B are provided in which the MIM capacitor 802 has a single trench structure 112a with a single gap 808a. In alternate embodiments, the wavelength tuner may comprise a plurality of trench structures as above. Further, two electrode-dielectric pairs are stacked over the lower capacitor electrode 804 to form the single trench structure 112a. Each electrode-dielectric pair comprises an upper capacitor electrode and a capacitor dielectric layer underlying the upper capacitor electrode. In alternative embodiments, the wavelength tuner may comprise more electrode-dielectric pairs.

A first electrode-dielectric pair comprises a first upper capacitor electrode 110a and a first capacitor dielectric layer 108a underlying the first upper capacitor electrode 110a to separate the first upper capacitor electrode 110a from the lower capacitor electrode 804. A second electrode-dielectric pair overlies the first electrode-dielectric pair. The second electrode-dielectric pair comprises a second upper capacitor electrode 110b and a second capacitor dielectric layer 108b underlying the second upper capacitor electrode 110b to separate the second upper capacitor electrode 110b from the first upper capacitor electrode 110a.

The lower capacitor electrode 804 and the second upper capacitor electrode 110b are electrically coupled (e.g., shorted) together at a common node. Further, during use of the MIM capacitor 802, the voltage V is applied from this common node to the first upper capacitor electrode 110a. Such electrical coupling may be achieved with an interconnect structure that electrically couples to electrodes of the MIM capacitor 802 via the lower conductive contact 118, a first upper conductive contact 120a, and a second upper conductive contact 120b. The first upper conductive contact 120a is atop the first upper capacitor electrode 110a, and the second upper conductive contact 120b is atop the second upper capacitor electrode 110b.

Electrically coupling the electrodes of the MIM capacitor 802 as above effectively creates two capacitors electrically coupled in parallel. A first capacitor is formed from the lower capacitor electrode 804, the first capacitor dielectric layer 108a, and the first upper capacitor electrode 110a. A second capacitor is formed from the first upper capacitor electrode 110a, the second capacitor dielectric layer 108b, and the second upper capacitor electrode 110b. Because capacitors in parallel are additive, the two capacitors forming the MIM capacitor 802 effectively increase a capacitance density of the MIM capacitor, which increases tuning efficiency.

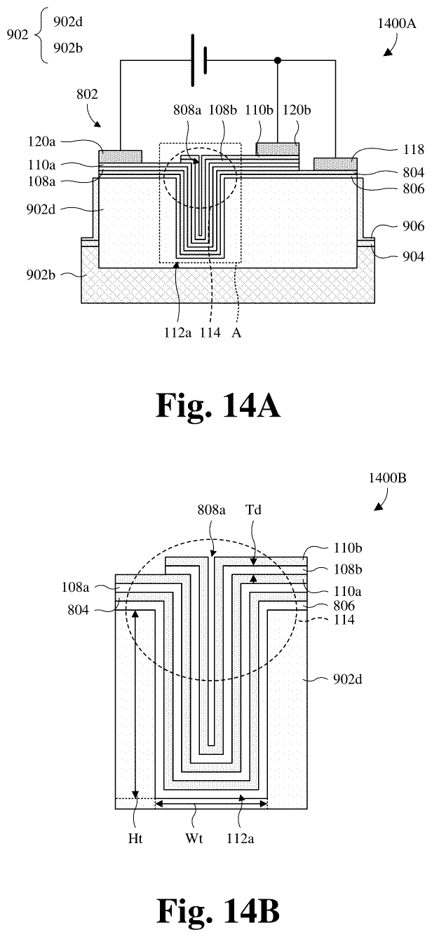

With reference to FIGS. 14A and 14B, cross-sectional views 1400A, 1400B of some alternative embodiments of the wavelength tuner of FIGS. 13A and 13B are provided in which the wavelength tuner has increased depth and extends into a semiconductor substrate 902 rather than a SOI substrate 126. The single trench structure 112a overlies and extends into a doped region 902d of the semiconductor substrate 902, which overlies and is inset into a bulk region 902b of the semiconductor substrate 902.

By forming the single trench structure 112a in the semiconductor substrate 902 rather than the semiconductor layer 106 of a SOI substrate 126, the single trench structure 112a can extend deeper than it would otherwise be able to. Hence, capacitance density may be further increased for enhanced tuning efficiency.

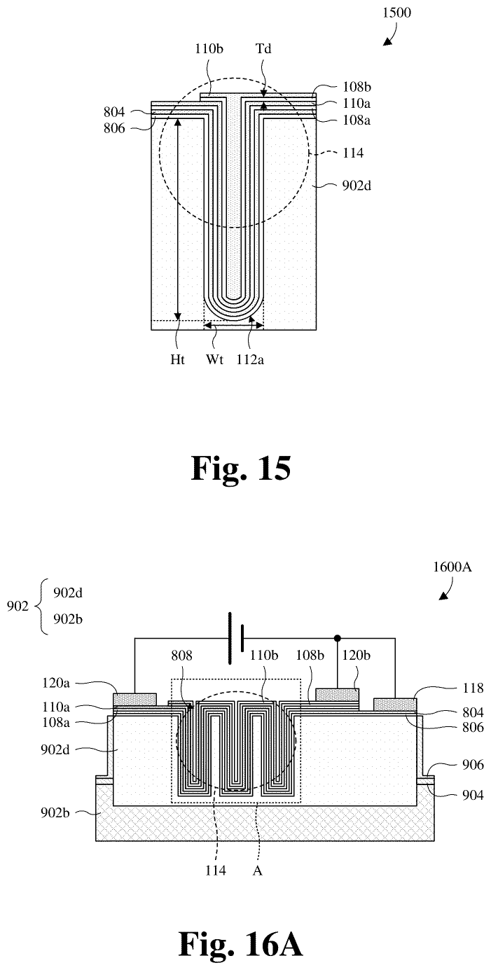

With reference to FIG. 15, a cross-sectional view 1500 of some alternative embodiments of the wavelength tuner of FIGS. 14A and 14B is provided in which lower surfaces of the MIM capacitor 802 are curved. Further, the single gap 808a is omitted.

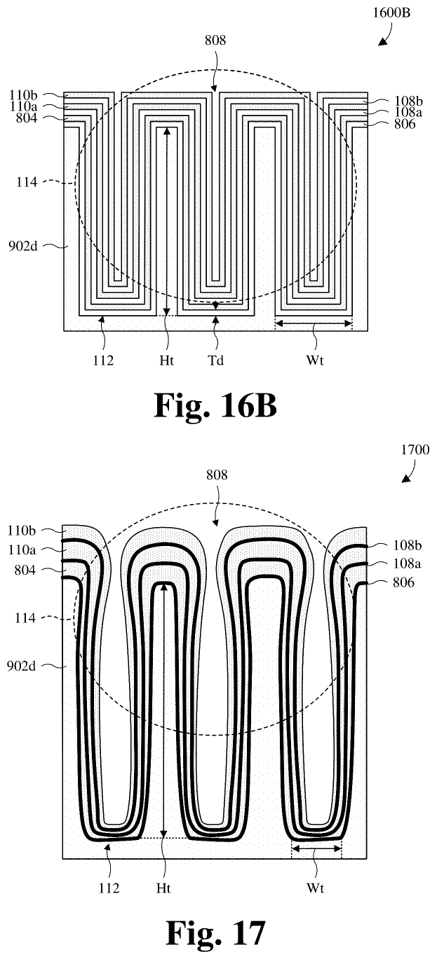

With reference to FIGS. 16A and 16B, cross-sectional views 1600A, 1600B of some alternative embodiments of the wavelength tuner of FIGS. 14A and 14B are provided in which the wavelength tuner has a plurality of trench structures 112 instead of a single trench structure. Further, the plurality of trench structures 112 have a plurality of gaps 808 at the trenches in which the plurality of trench structures 112 are arranged.

In some embodiments, the MIM capacitor 802 has a capacitance density of about 397 fF/um², about 200-350 fF/um², about 350-450 fF/um², about 450-600 fF/um², or some other suitable value. Further, in some embodiments, the MIM capacitor 802 has tuning efficiency of about 7000 pm/V, about 5500-6500 pm/V, 6500-7500 pm/V, about 7500-8500 pm/V, or some other suitable value.

With reference to FIG. 17, a cross-sectional view 1700 of some alternative embodiments of the wavelength tuner of FIGS. 16A and 16B is provided in which the surfaces of the MIM capacitor 802 are less rectilinear. Further, for ease of illustration, the capacitor dielectric layer 108 and the buffer dielectric layer 806 are shown as thick, black lines.

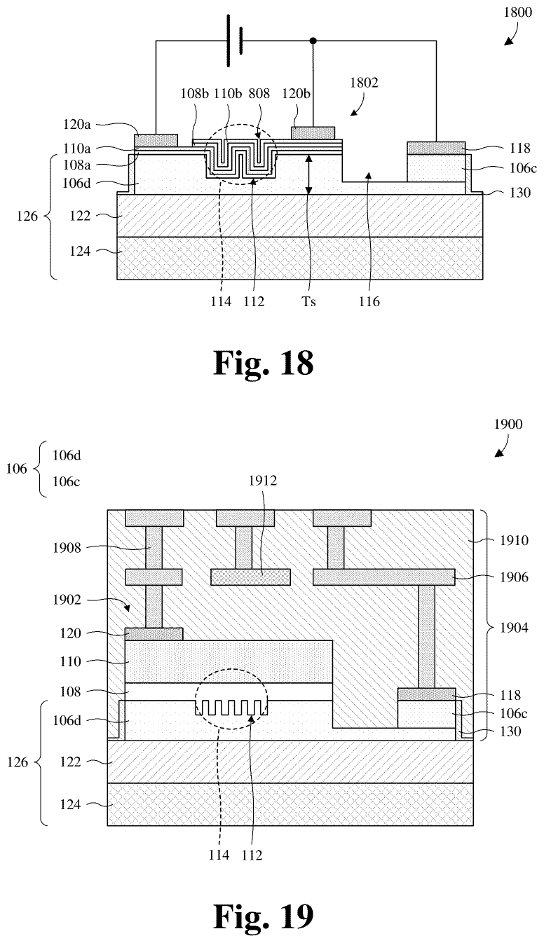

With reference to FIG. 18, a cross-sectional view 1800 of some alternative embodiments of the wavelength tuner of FIGS. 1A and 1B is provided in which the wavelength tuner comprises a capacitor 1802 formed from a combination of the MOSCAP 102 and the MIM capacitor 802. The doped region 106d is employed as a lower capacitor electrode, and a first upper capacitor electrode 110a and a second upper capacitor electrode 110b are stacked over the doped region 106d. The first upper capacitor electrode 110a overlies the doped region 106d and is separated from the doped region 106d by a first capacitor dielectric layer 108a. The second upper capacitor electrode 110b overlies the first upper capacitor electrode 110a and is separated from the first upper capacitor electrode 110a by a second capacitor dielectric layer 108b.

The doped region 106d, the first capacitor dielectric layer 108a, and the first upper capacitor electrode 110a correspond to a MOSCAP, whereas the first upper capacitor electrode 110a, the second capacitor dielectric layer 108b, and the second upper capacitor electrode 110b correspond to a MIM capacitor. The MIM capacitor comprises a single electrode-dielectric pair stacked over the MOSCAP and formed by the second capacitor dielectric layer 108b and the second upper capacitor electrode 110b. In alternative embodiments, the MIM capacitor may comprise one or more additional electrode-dielectric pairs stacked over the MOSCAP. As above, each electrode-dielectric pair comprises an upper capacitor electrode and a capacitor dielectric layer underlying the upper capacitor electrode.

The first and second upper capacitor electrodes 110a, 110b and the first and second capacitor dielectric layers 108a, 108b line trenches in the doped region 106d to form the plurality of trench structures 112. Further, a plurality of gaps 808 remain at the trenches. The lower capacitor electrode 804 and the second upper capacitor electrode 110b are electrically coupled (e.g., shorted) together at a common node.

During use of the capacitor 1802, a light beam 114 is passed through the plurality of trench structures 112 while the capacitor 1802 is biased with a voltage V. The voltage V is applied from the first upper capacitor electrode 110a to a common node to which the doped region 106d and the second upper capacitor electrode 110b are electrically coupled. Such electrical coupling may be achieved with an interconnect structure that electrically couples to electrodes of the capacitor 1802 via the lower conductive contact 118, a first upper conductive contact 120a, and a second upper conductive contact 120b. The first upper conductive contact 120a is atop the first upper capacitor electrode 110a, and the second upper conductive contact 120b is atop the second upper capacitor electrode 110b.

As with the MOSCAP 102 and the MIM capacitor 802, the tuning efficiency of the capacitor 1802 is proportional to capacitance density. Because of the plurality of trench structures 112, capacitance density of the capacitor 1802 is increased at the light beam 114 and hence tuning efficiency (e.g., wavelength shift per unit voltage) is increased. Because of the plurality of trench structures 112, contact area between capacitor electrode and capacitor dielectric layer is increased. The increased contact areas reduce contact resistance and may hence reduce RC delay of the capacitor 1802 to improve EO and OE signal conversions.

With reference to FIG. 19, a cross-sectional view 1900 of some embodiments of an integrated circuit (IC) chip comprising a wavelength tuner 1902 according to aspects of the present disclosure. The wavelength tuner 1902 is configured as in FIGS. 1A and 1B but may alternatively be configured as in any one or combination of FIG. 2 to FIG. 18.

An interconnect structure 1904 overlies and electrically couples to the wavelength tuner 1902. The interconnect structure 1904 comprises a plurality of wires 1906 and a plurality of vias 1908 stacked in an interconnect dielectric layer 1910. The plurality of wires 1906 are grouped into a plurality of wire levels, and the plurality of vias 1908 are grouped into a plurality of via levels alternatingly stacked with the plurality of wire levels. The various wire and via levels form conductive paths leading from conductive contacts (e.g., the lower and upper conductive contacts 118, 120) of the wavelength tuner 1902. The plurality of wires 1906 and the plurality of vias 1908 may, for example, be or comprise copper, aluminum copper, tungsten, some other suitable metal, or any combination of the foregoing.

In some embodiments, a heater 1912 overlies the wavelength tuner 1902 and is electrically coupled to the interconnect structure 1904. The heater 1912 may, for example, be a resistive heater or some other suitable type of heater. The heater 1912 may, for example, be employed for further wavelength tuning. Because of the high tuning efficiency of the wavelength tuner 1902, dependence on the heater 1912 for tuning may be reduced, whereby power consumption of the heater 1912 may be reduced.

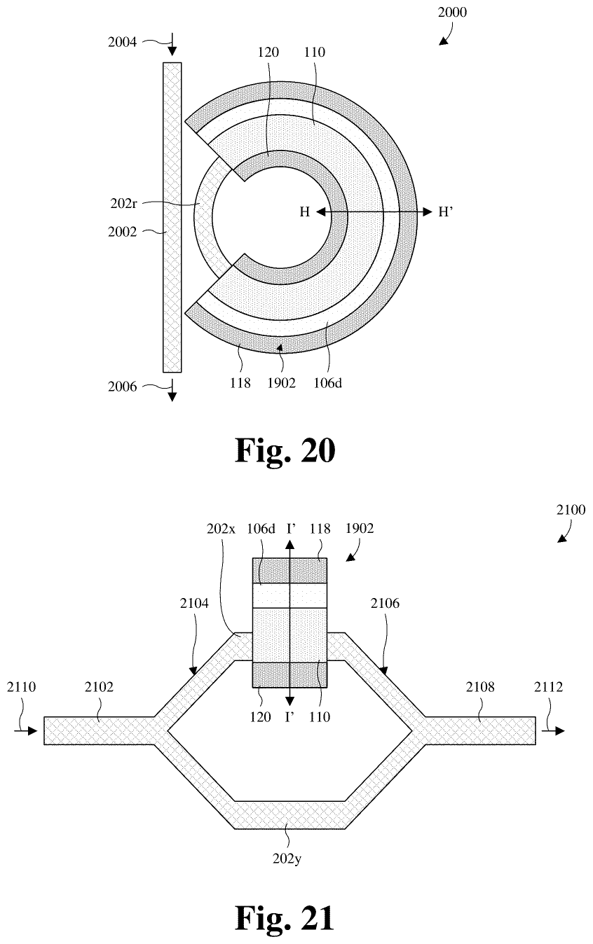

With reference to FIG. 20, a top view 2000 of some embodiment of a ring modulator comprising a wavelength tuner 1902 according to aspects of the present disclosure is provided. In some embodiments, the wavelength tuner in any one or combination of FIGS. 1A, 1B, 5A, 5B, 6A, 6B, 7A-7D, and 19 may, for example, be taken along line H-H′. In alternative embodiments, the top view 2000 may be varied and any one or combination of FIGS. 7E, 8A, 8B, 9A, 9B, 10, 13A, 13B, 14A, 14B, 15, 16A, 16B, 17, and 18 may be taken along line H-H′. Further, in some embodiments, the ring modulator may also be known as a micro-ring modulator (MRM) or some other suitable name.

The ring modulator comprises the wavelength tuner 1902 and a ring waveguide 202r arranged to form a ring-shaped optical path. In some embodiments, a portion of the wavelength tuner 1902 through which light passes may correspond to a doped portion of the ring waveguide 202r. As such, the wavelength tuner 1902 may be regarded as being integrated with the ring waveguide 202r. In alternative embodiments, a portion of the wavelength tuner 1902 through which light passes may be a different material than the ring waveguide 202r and may hence be regarded as its own waveguide that extends from the ring waveguide 202r.

A bus waveguide 2002 borders the ring waveguide 202r and is coupled to the ring waveguide 202r. Such coupling may, for example, be by evanescent field coupling and/or by some other suitable coupling mechanism. The bus waveguide 2002 carries light 2004 into the ring modulator and carries modulated light 2006 out of the ring modulator.

The ring-shaped optical path formed by the wavelength tuner 1902 and the ring waveguide 202r has a resonant wavelength. Light with a wavelength corresponding to the resonant wavelength couples from the bus waveguide 2002 to the ring waveguide 202r. Light with off-resonant wavelengths does not couple, or couples only minimally, to the ring waveguide 202r and passes the ring modulator largely unchanged. Hence, the ring modulator filters light at the resonant wavelength from the bus waveguide 2002.

The ring modulator is configured (e.g., appropriately sized) so as to have a resonant wavelength corresponding to a target wavelength. Further, by modulating the voltage across the wavelength tuner 1902, this resonant wavelength can be varied. Because the ring modulator filters light at the resonant wavelength from the bus waveguide 2002, varying the resonant wavelength allows the amplitude of the target wavelength to be modulated.

The ring waveguide 202r and the bus waveguide 2002 each comprise a core structure and a cladding around the core structure. For ease of illustration, cladding around the core structure is hidden so the core structure may be seen from the top view 2000. The cladding may be a solid, an air gap, or some other suitable type of cladding. The core/cladding materials may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or the like.

With reference to FIG. 21, a top view 2100 of some embodiment of a Mach-Zehnder modulator (MZM) comprising a wavelength tuner 1902 according to aspects of the present disclosure is provided. The wavelength tuner 1902 may, for example, correspond to the wavelength tuner in any one or combination of FIG. 1A through FIG. 18. In some embodiments, the cross-sectional view in any one of FIGS. 1A, 1B, 5A, 5B, 6A, 6B, 7A-7D, and 19 may, for example, be taken along line F-F′. In alternative embodiments, the top view 2100 may be varied and the cross-sectional view in any one of FIGS. 7E, 8A, 8B, 9A, 9B, 10, 13A, 13B, 14A, 14B, 15, 16A, 16B, 17, and 18 may be taken along line I-I′.

The MZM modulator comprises an input waveguide 2102 extending to an input of an optical splitter 2104. The optical splitter 2104 has two outputs, which are coupled to a first arm waveguide 202x and a second arm waveguide 202y. The first and second arm waveguides 202x, 202y lead to two inputs of an optical combiner 2106. The optical combiner 2106 has an output, which is coupled to an output waveguide 2108.

The wavelength tuner 1902 is arranged between two segments of the first arm waveguide 202x. In some embodiments, a portion of the wavelength tuner 1902 through which light passes may correspond to a doped portion of the first arm waveguide 202x. As such, the wavelength tuner 1902 may be regarded as being integrated with the first arm waveguide 202x. In alternative embodiments, a portion of the wavelength tuner 1902 through which light passes may be a different material than the first arm waveguide 202x and may hence be regarded as its own waveguide that separates the two segments of the first arm waveguide 202x.

Light 2110 enters the input waveguide 2102 and is split amongst the first arm waveguide 202x and the second arm waveguide 202y by the optical splitter 2104. Further, light in the two arm waveguides 202x, 202y undergoes a phase difference, which determines whether the light constructively or destructively interferes when combined at the optical combiner 2106. Constructive interference allows light to pass to the output waveguide 2108, while destructive interference suppresses transmission to the output waveguide 2108.

By modulating the voltage applied to the wavelength tuner 1902, the phase shift at the first arm waveguide 202x can be varied. As a result, the extent of constructive and destructive interference at the optical combiner 2106 may be varied by the wavelength tuner 1902. This, in turn, allows modulating the amplitude of the light passing through the wavelength tuner 1902 and modulated light 2112 to be output via the output waveguide 2108.

In some embodiments, the input waveguide 2102, the output waveguide 2108, the first arm waveguide 202x, and the second arm waveguide 202y each comprise a core structure and a cladding around the core structure. For ease of illustration, cladding around the core structure is hidden so the core structure may be seen from the top view 2100. The cladding may be a solid, an air gap, or some other suitable type of cladding. The core/cladding materials may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or the like.

In some embodiments, the optical splitter 2104 is or comprises a directional coupler, a Y-junction, or some other suitable type of optical splitter. Further, in some embodiments, the optical combiner 2106 is or comprises a directional coupler, a Y-junction, or some other suitable type of optical splitter. In some embodiments, the optical splitter 2104 and the optical combiner 2106 have a composition similar to the above waveguides and hence each comprise a core structure and a cladding around the core structure. The core material and/or the cladding material may, for example, be as described above for the waveguides.

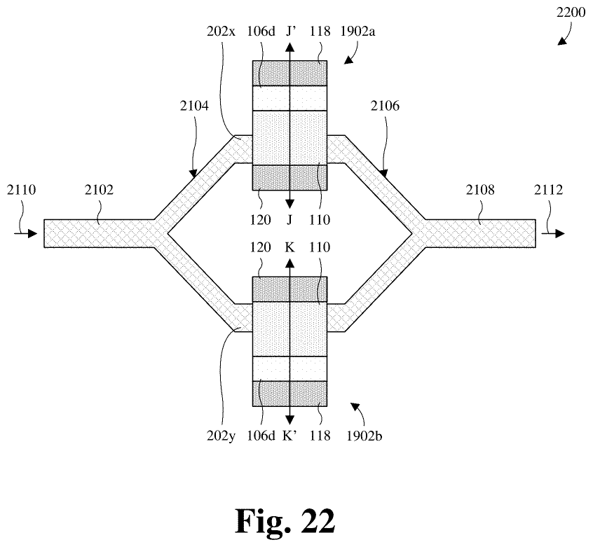

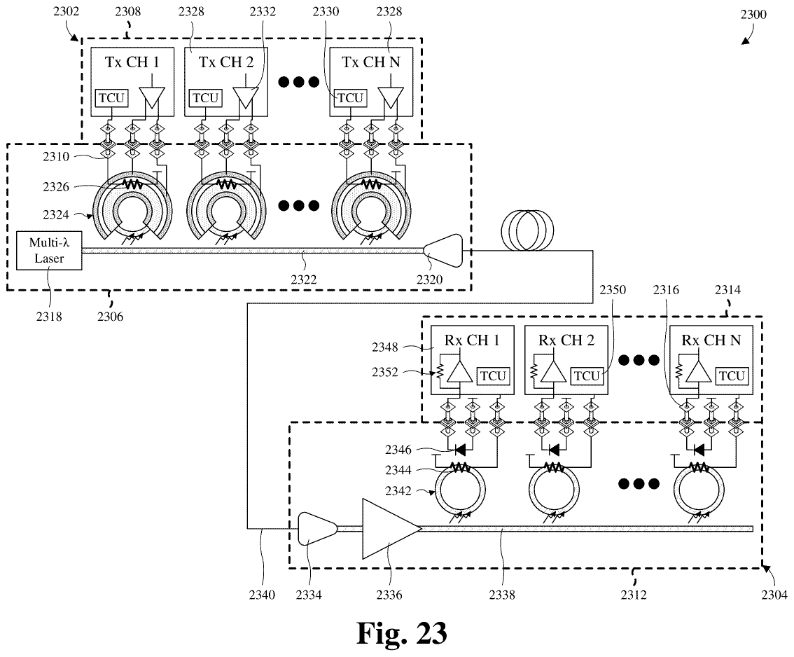

With reference to FIG. 22, a top view 2200 of some embodiment of some alternative embodiments of the MZM of FIG. 21 is provided in which the MZM comprises a first wavelength tuner 1902a and a second wavelength tuner 1902b according to aspects of the present disclosure is provided. In contrast, FIG. 21 has only one wavelength tuner.

The first wavelength tuner 1902a and the second wavelength tuner 1902b are each as the wavelength tuner 1902 of FIG. 21 is illustrated and described. However, the first wavelength tuner 1902a is on the first arm waveguide 202x, whereas the second wavelength tuner 1902b is on the second arm waveguide 202y. In some embodiments, the cross-sectional view in any one of FIGS. 1A, 1B, 5A, 5B, 6A, 6B, 7A-7D, and 19 may, for example, be taken along line J-J′ and/or along line K-K′. In alternative embodiments, the top view 2000 may be varied and the cross-sectional view in any one of FIGS. 7E, 8A, 8B, 9A, 9B, 10, 13A, 13B, 14A, 14B, 15, 16A, 16B, 17, and 18 may be taken along line J-J′ and/or along line K-K′.

By modulating the voltages applied to the first and second wavelength tuners 1902a, 1902b, phase shifts of light respectively at the first and second arm waveguides 202x, 202y may be varied. As noted above, the MZM uses a phase difference between light at the first and second wavelength tuners 1902a, 1902b to achieve constructive and/or destructive interference at the optical combiner 2106. Hence, by controlling the phase shifts at the first and second arm waveguides 202x, 202y, the phase difference may be controlled. This allows the extent of constructive and destructive interference to be controlled, which allows amplitude modulation. Having two wavelength tuners rather than one provides a greater degree of control over the phase difference and hence over the amplitude modulation.

With reference to FIG. 23, a schematic view 2300 of some embodiments of a system comprising an optical transmitter 2302 and an optical receiver 2304 according to aspects of the present disclosure is provided. The system may, for example, employ wavelength division multiplexing (WDM), pulse-amplitude modulation (PAM), or the like for transmission of data from the optical transmitter 2302 to the optical receiver 2304.

The optical transmitter 2302 comprises a transmit photonic integrated circuit (Tx PIC) 2306 and a transmit electronic integrated circuit (Tx EIC) 2308 that are bonded and electrically coupled together via a plurality of first conductive features 2310. Similarly, the optical receiver 2304 comprises a receive photonic integrated circuit (Rx PIC) 2312 and a receive electronic integrated circuit (Rx EIC) 2314 that are bonded and electrically coupled together via a plurality of second conductive features 2316.

The Tx PIC 2306 includes a laser 2318, an output coupler 2320, and a transmit bus waveguide 2322 extending from the laser 2318 to the output coupler 2320. The laser 2318 is configured to generate a multi-wavelength laser beam that passes through the transmit bus waveguide 2322 to the output coupler 2320.

A plurality of ring modulators 2324 and a plurality of transmit heaters 2326 are in the Tx PIC 2306, spaced along the transmit bus waveguide 2322. The plurality of ring modulators 2324 are each as in FIG. 20 and/or each comprise a wavelength tuner according to any one or combination of FIGS. 1A through 18. The plurality of ring modulators 2324 have different resonant wavelengths and are hence configured to modulate different wavelengths. The plurality of transmit heaters 2326 are individual to the plurality of ring modulators 2324 and respectively overlap with the plurality of ring modulators 2324. The plurality of transmit heaters 2326 are configured to tune a resonant frequency of the plurality of ring modulators 2324. As noted above, because the plurality of ring modulators 2324 use wavelength tuners according to aspects of the present disclosure, which have larger wavelength tuning efficiency and range, use of the plurality of transmit heaters 2326 may be reduced to reduce power consumption.

The Tx EIC 2308 comprises a plurality of transmit channels 2328, which comprise individual tuning control units 2330 and individual amplifiers 2332. The tuning control units 2330 are configured to control heating and are electrically coupled to the plurality of transmit heaters 2326 via the plurality of first conductive features 2310. The amplifiers 2332 are configured to drive the plurality of ring modulators 2324 and are electrically coupled to the plurality of ring modulators 2324 via the plurality of first conductive features 2310.

The RX PIC 2312 includes an input coupler 2334, an optical amplifier 2336, and a receive bus waveguide 2338. The input coupler 2334 is optically coupled to the output coupler 2320 via an optical fiber 2340. The receive bus waveguide 2338 extends from the input coupler 2334, and the optical amplifier 2336 is arranged along the receive bus waveguide 2338 to amplify optical signals carried on the receive bus waveguide 2338. Further, the RX PIC 2312 includes a plurality of ring receivers 2342, a plurality of receive heaters 2344, and a plurality of photodetectors 2346 that are spaced along the receive bus waveguide 2338.

Similar to the plurality ring modulators 2324, the plurality of ring receivers 2342 have ring-shaped optical paths with resonant wavelengths. Light with a wavelength corresponding to the resonant wavelength of a ring receiver couples into the ring receiver from the receive bus waveguide 2338 and is sensed by a corresponding one of the plurality of photodetectors 2346. Light with a wavelength offset from the resonant wavelength of a ring receiver moves along the receive bus waveguide 2338 and possibly couples to another ring receiver.

The plurality of receive heaters 2344 are individual to the plurality of ring receivers 2342 and respectively overlap with the plurality of ring receivers 2342. Further, the plurality of receive heaters 2344 are configured to tune resonant frequencies of the plurality of ring receivers 2342. In alternative embodiments, the plurality of receive heaters 2344 may be replaced with wavelength tuners according to aspects of the present disclosure. For example, the wavelength tuners in any one or combination of FIGS. 1A through 18 may be used in place of the plurality of receive heaters 2344 to tune the resonant frequencies. This may, for example, be employed for enhanced power efficiency due to the higher power use of heaters.

The Rx EIC 2314 comprises a plurality of receive channels 2348, which comprise individual tuning control units 2350 and individual amplifiers 2352. The tuning control units 2330 are configured to control heating and are electrically coupled to the plurality of receive heaters 2344 via the plurality of second conductive features 2316. The amplifiers 2352 are configured to amplify signals from the plurality of photodetectors 2346 and are electrically coupled to the plurality of photodetectors 2346 via the plurality of second conductive features 2316.

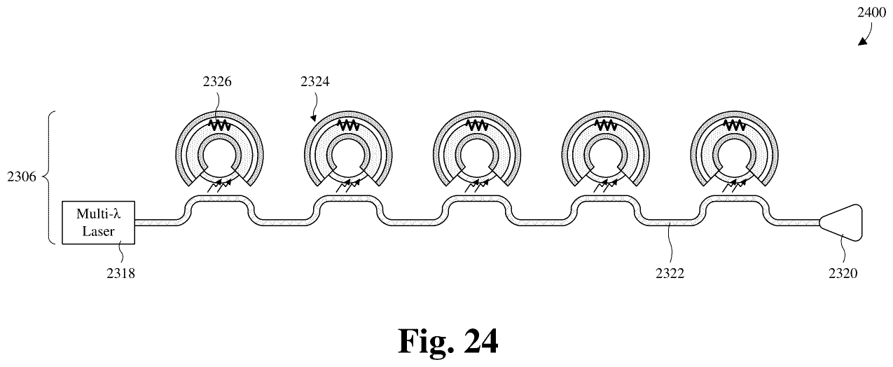

With reference to FIG. 24, a schematic view 2400 of some alternative embodiments of the Tx PIC 2306 of FIG. 23 is provided in which the transmit bus waveguide 2322 is non-linear. Further, the plurality of ring modulators 2324 have five ring modulators rather than the three or more shown in FIG. 23. Such modulators may, for example, be employed for four-level pulse amplitude modulation (PAM4) or some other suitable modulation scheme.

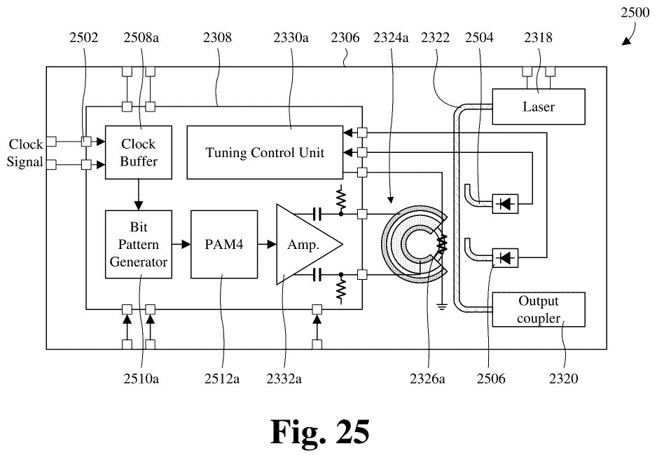

With reference to FIG. 25, a schematic view 2500 of some embodiments of an optical transmitter according to aspects of the present disclosure is provided. The optical transmitter comprises a Tx EIC 2308 overlapping with and bonded to a Tx PIC 2306. Further, pads 2502 are arranged throughout the optical transmitter and provide locations for coupling the Tx PIC 2306 and the Tx EIC 2308 together and to external circuitry.

The Tx PIC 2306 accommodates a ring modulator 2324a and a heater 2326a that overlaps with the ring modulator 2324a. The ring modulator 2324a includes a wavelength tuner configured as in any of FIGS. 1A through 18 and may, for example, correspond to the ring modulator of FIG. 20. The ring modulator 2324a borders a transmit bus waveguide 2322 extending from an output of a laser 2318 to an input of an output coupler 2320. Monitor waveguides 2504 and monitor photodetectors 2506 couple to the transmit bus waveguide 2322 (e.g., by evanescent field coupling) to provide feedback to the Tx EIC 2308.

The Tx EIC 2308 controls the ring modulator 2324a and the heater 2326a. The Tx EIC 2308 comprises a clock buffer 2508a, a tuning control unit 2332a, a bit pattern generator 2510a, an encoder 2512a, and an amplifier 2330a. The clock buffer 2508a buffers an external clock signal and passes the buffered clock signal to the bit pattern generator 2510a. The bit pattern generator 2510a provides a stream of bits to the encoder 2512a, which generates a control signal based on the stream of bits. In some embodiments, the encoder 2512a is configured for PAM4 encoding, and/or comprises non-linear pre-distortion and/or non-linear equalization. The amplifier 2330a drives the ring modulator 2324a based on the control signal to modulate a wavelength of light from the laser 2318.

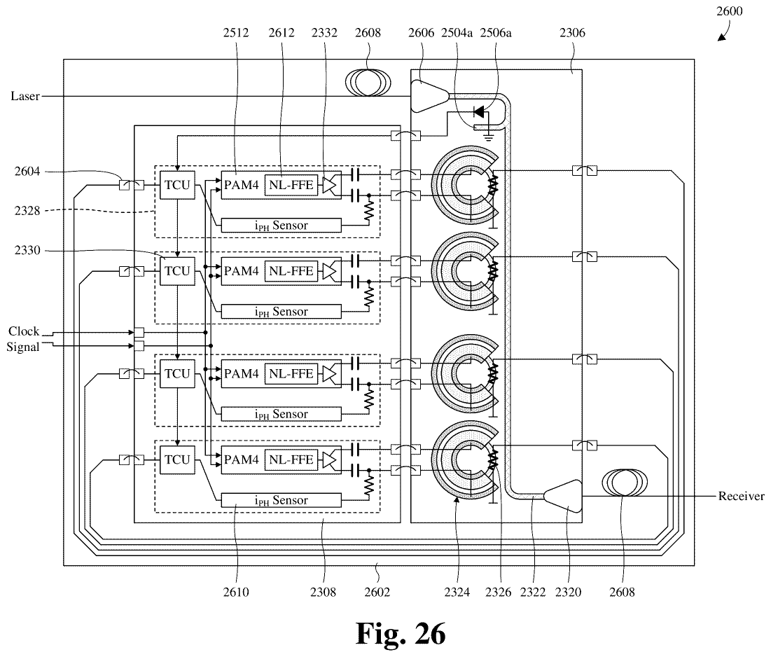

With reference to FIG. 26, a schematic view 2600 of some other embodiments of an optical transmitter according to aspects of the present disclosure is provided. The optical transmitter comprises a Tx EIC 2308 and a Tx PIC 2306 that overlap with and are bonded to a circuit board 2602. Further, pads 2604 are arranged through the optical transmitter and provide locations for coupling the Tx PIC 2306 and the Tx EIC 2308 together, to the circuit board 2602, and to external circuitry.

The Tx PIC 2306 accommodates a plurality of ring modulators 2324 and a plurality of transmit heaters 2326 overlapping with the plurality of ring modulators 2324. The plurality of ring modulators 2324 each include a wavelength tuner configured as in any of FIGS. 1A through 18 and may, for example, correspond to the ring modulator of FIG. 20. The plurality of ring modulators 2324 border a transmit bus waveguide 2322 extending from an input coupler 2606 to an output coupler 2320. The input coupler 2606 and the output coupler 2320 are coupled respectively to fiber optic cables 2608. A monitor waveguide 2504a and a monitor photodetector 2506a couple to the transmit bus waveguide 2322 to provide feedback to the Tx EIC 2308.

The Tx EIC 2308 controls the plurality of ring modulators 2324 and the plurality of transmit heaters 2326. The Tx EIC 2308 comprises a plurality of channels 2328 comprising individual tuning control units 2330, individual encoders 2512, individual amplifiers 2332, and individual photocurrent sensors 2610. In some embodiments, the encoders 2512 are PAM4 encoders and/or comprise individual Non-Linear Feed-Forward Equalizers (NP-FFEs) 2612. The tuning control units 2330, the individual encoders 2512, and the individual amplifiers 2332 function as above.

The photocurrent sensors 2610 measure photocurrent from PIN junctions of wavelength tuners in the plurality of ring modulators 2324. For example, a lower capacitor electrode (e.g., 106d in FIG. 1A) of the wavelength tuner may be or comprise monocrystalline silicon with a first doping type (e.g., P or N), an upper capacitor electrode (e.g., 110 in FIG. 1A) of the wavelength tuner may be or comprise doped polysilicon with an opposite doping type (e.g., N or P), and a capacitor dielectric layer (e.g., 108 in FIG. 1A) may separate the two electrodes. Measurements from the photocurrent sensors 2610 may be used by the tuning control units 2330 as a basis for controlling the transmit heaters 2326.

In alternative embodiments, the photocurrent sensors 2610 are omitted. Without reliance on PIN junctions, the available materials for lower and upper capacitor electrodes of the wavelength tuners are increased.

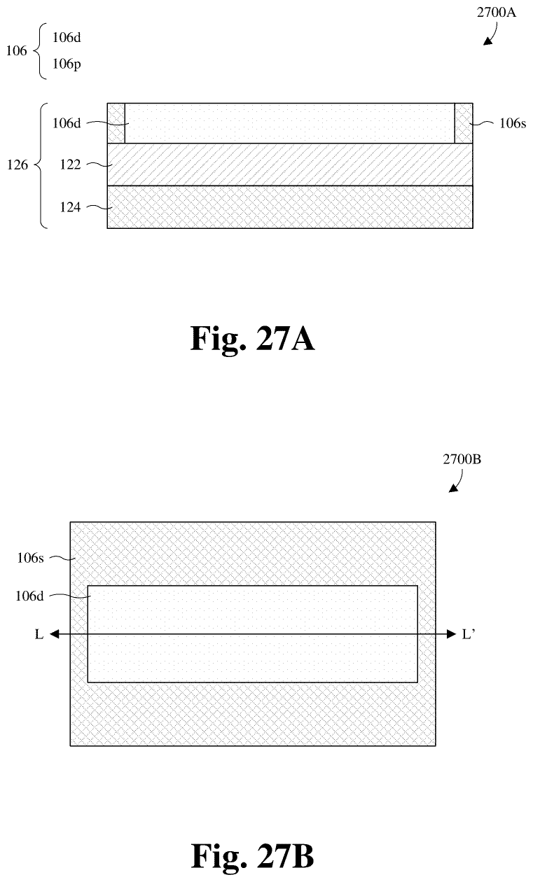

With reference to FIGS. 27A and 27B to FIGS. 30A and 30B and FIGS. 31-38, a series of views of some embodiments of a method for forming a wavelength tuner comprising a capacitor is provided. Figures labeled with a suffix of A or with no letter suffix correspond to cross-sectional views, whereas figures labeled with a suffix of B correspond to top views for like numbered figures. Further, figures labeled with a suffix of A may, for example, be taken along line L-L′ in like numbered figures labeled with a suffix of B. The method may, for example, be employed to form the wavelength tuner in any one or combination of FIGS. 1A, 1B, 2, 3A, and 3B. Hence, the capacitor may be a MOSCAP. Alternatively, the method may, for example, be employed to form some other suitable wavelength tuner as described above in any one or combination of FIGS. 4A through 18.

As illustrated by the views 2700A, 2700B of FIGS. 27A and 27B, a semiconductor layer 106 is selectively doped to form a doped region 106d in the semiconductor layer 106. The doped region 106d has an elevated doping concentration relative to a surrounding region 106s of the semiconductor layer 106, which may be undoped or lightly doped. The selective doping may, for example, be performed by ion implantation with a mask in place or by some other suitable doping process. As seen hereafter, the doped region 106d may, for example, correspond to a lower capacitor electrode of the MOSCAP being formed as part of the wavelength tuner.

An insulator layer 122 underlies the semiconductor layer 106 and a handle substrate 124 underlies the insulator layer 122. In some embodiments, the semiconductor layer 106, the insulator layer 122, and the handle substrate 124 form an SOI substrate 126.

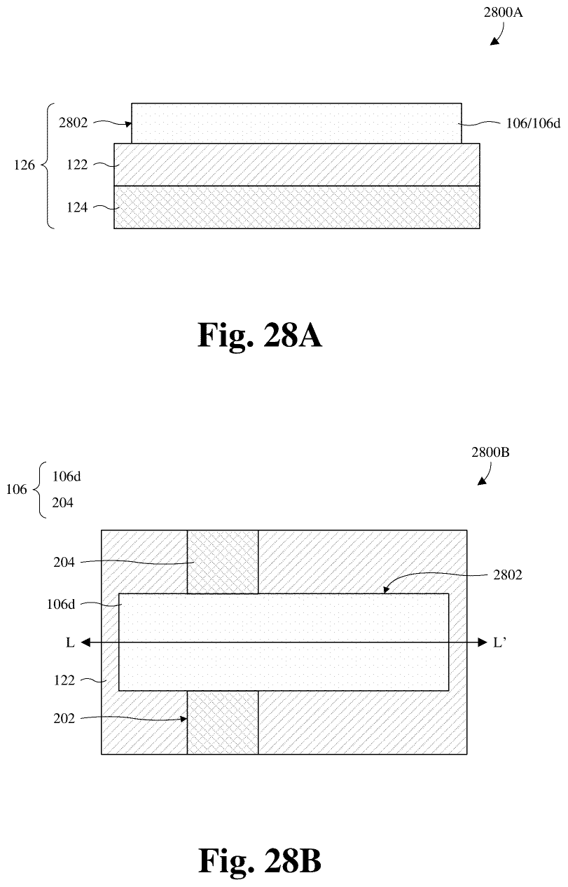

As illustrated by the views 2800A, 2800B of FIGS. 28A and 28B, the semiconductor layer 106 is patterned to form a mesa 2802 at the doped region 106d. Further, the patterning forms the core structure 204 of a waveguide 202 adjoining the mesa 2802. The core structure 204 is configured to lead light through the wavelength tuner for wavelength tuning of the light. In alternative embodiments, the core structure 204 of the waveguide 202 is formed of a different material than the semiconductor layer 106 and is hence formed independent of the patterning, before, during, or after formation of the wavelength tuner.

The patterning may, for example, be performed by a photolithography/etching process or by some other suitable patterning process. For example, a mask is formed over the semiconductor layer 106 using photolithography and then an etch is performed into the semiconductor layer 106 with the mask in place. In some embodiments, the etch extends to the insulator layer 122 underlying the semiconductor layer 106.

In some embodiments, the wavelength tuner is formed as part of the ring modulator of FIG. 20 and corresponds to the wavelength tuner 1902 of FIG. 20. In such embodiments, the waveguide 202 corresponds to the ring waveguide 202r of FIG. 20, and the waveguide 202 and the mesa 2802 have a ring-shaped top geometry. Further, in such embodiments, a bus waveguide is formed with the waveguide 202 and is formed bordering the waveguide 202. In other embodiments, the wavelength tuner is formed as part of the MZM modulator of FIG. 21 or 22 and corresponds to the wavelength tuner 1902 of FIG. 21 or 22. In such embodiments, the waveguide 202 corresponds to the first arm waveguide 202x or the second arm waveguide 202y in FIG. 21 or 22. Further, in such embodiments, the input waveguide 2102, the output waveguide 2108, the optical splitter 2104, and the optical combiner 2106 are formed with the waveguide 202.

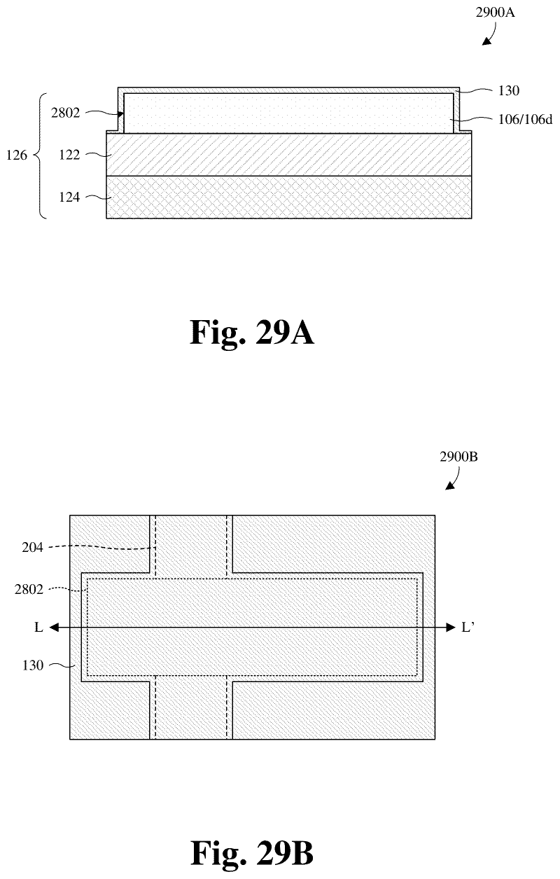

As illustrated by the views 2900A, 2900B of FIGS. 29A and 29B, a cladding layer 130 is deposited. The cladding layer 130 overlies the semiconductor layer 106 and the insulator layer 122 and further lines sidewalls of the semiconductor layer 106. The cladding layer 130 and the insulator layer 122 surround the mesa 2802 and the core structure 204 of the waveguide 202 to confine light within the mesa 2802 and the core structure 204.

The cladding layer 130 may, for example, be a solid, an air gap, or some other suitable type of cladding. Further, the core structure/cladding layer may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or the like.

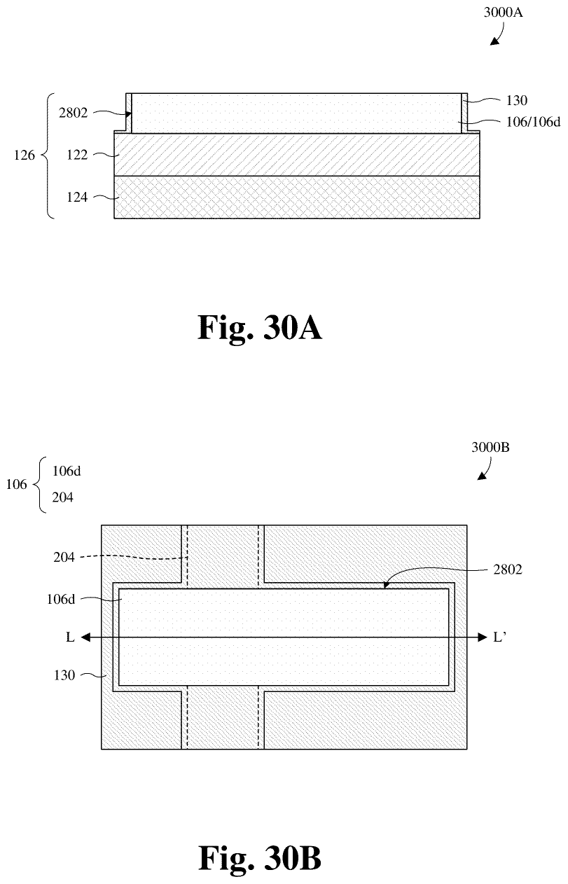

As illustrated by the views 3000A, 3000B of FIGS. 30A and 30B, the cladding layer 130 is removed from atop the mesa 2802 without removing the cladding layer 130 from atop the core structure 204 of the waveguide 202. Such removal may, for example, be performed by a photolithography/etching process or by some other suitable removal process. The etching may, for example, be performed by a reactive ion etch (RIE) or by some other suitable etch.

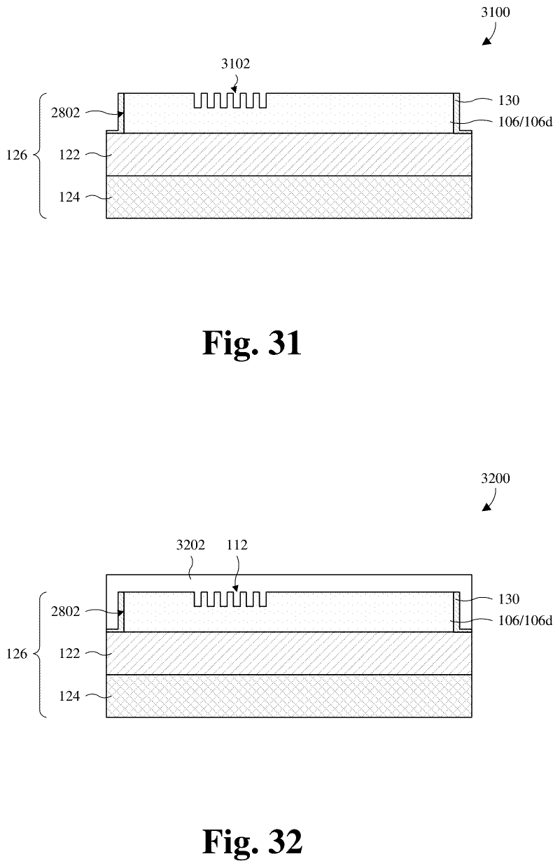

As illustrated by the view 3100 of FIG. 31, the mesa 2802 is patterned to form a plurality of trenches 3102 extending into the mesa 2802. As shown, six trenches are shown but more or less trenches are amenable. Further, different depths for the trenches are amenable. The patterning may, for example, be performed by a photolithography/etching process or by some other suitable patterning process.

As illustrated by the view 3200 of FIG. 32, a dielectric layer 3202 is deposited overlying the mesa 2802 and filling the plurality of trenches 3102 of FIG. 31. Portions of the dielectric layer 3202 filling the plurality of trenches 3102 form a plurality of trenches structures 112, which as described above, increase tuning efficiency of the wavelength being formed. In some embodiments, after depositing the dielectric layer 3202, a planarization is performed into the dielectric layer 3202 to flatten a top surface of the dielectric layer 3202. The dielectric layer 3202 may, for example, be or comprise silicon oxide, a high-k dielectric material, some other suitable dielectric material, or any combination of the foregoing.

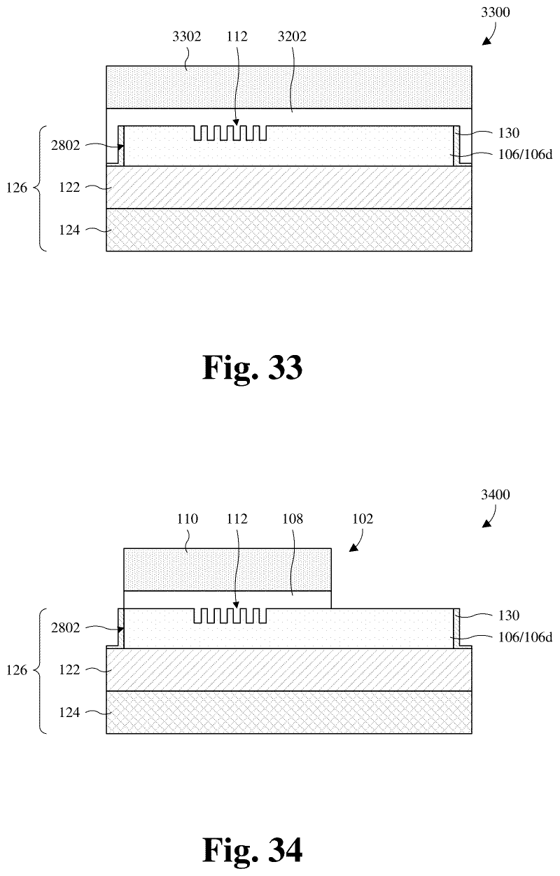

As illustrated by the view 3300 of FIG. 33, a conductive layer 3302 is deposited overlying the dielectric layer 3202. The conductive layer 3302 may, for example, be or comprise metal, a metal-containing material, a semiconductor material, some other suitable conductive material, or any combination of the foregoing. The metal or metal-containing material may, for example, be or comprise titanium nitride (e.g., TiN), aluminum (e.g., Al), tantalum nitride (e.g., TaN), tungsten (e.g., W), copper (e.g., Cu), ruthenium (e.g., Ru), some other suitable conductive material, or any combination of the foregoing. The semiconductor material may, for example, be or comprise doped polysilicon and/or some other suitable material.

To the extent that the conductive layer 3302 is or comprises a semiconductor material, the semiconductor material has a different conductivity type (e.g., doping type) as the doped region 106d. Further, in some embodiments, the doped region 106d and the conductive layer 3302 are a common semiconductor material but have different crystallinities. For example, the doped region 106d may be P-type monocrystalline silicon, whereas the conductive layer 3302 may be N-type polycrystalline silicon (e.g., polysilicon).

As illustrated by the view 3400 of FIG. 34, the conductive layer 3302 and the dielectric layer 3202 are patterned to respectively form an upper capacitor electrode 110 and a capacitor dielectric layer 108 atop the mesa 2802, at the plurality of trench structures 112. The capacitor dielectric layer 108 corresponds to a segment of the dielectric layer 3202 between the upper capacitor electrode 110 and the mesa 2802. The patterning may, for example, be performed by a photolithography/etching process or by some other suitable patterning process.

The doped region 106d, the capacitor dielectric layer 108, and the upper capacitor electrode 110 form a MOSCAP 102, and the doped region 106d serves as a lower capacitor electrode for the MOSCAP 102. During use of the wavelength tuner, a light beam is passed through the MOSCAP 102 while the MOSCAP 102 is biased with a voltage applied from the doped region 106d to the upper capacitor electrode 110. The light beam may, for example, be passed through the MOSCAP 102 by the waveguide 202 seen in FIGS. 27A and 27B to FIGS. 29A and 29B or the like. The voltage causes the accumulation of free charge carriers (e.g., electrons or holes) at the interface between the doped region 106d and the capacitor dielectric layer 108. By modulating the voltage, carrier concentration and hence refractive index of the doped region 106d are modulated to wavelength tune the light beam.

As confirmed experimentally, capacitance density is proportional to tuning efficiency. Because of the plurality of trench structures 112, capacitance density of the MOSCAP 102 is increased at the light beam and hence tuning efficiency (e.g., wavelength shift per unit voltage) is increased. As a result, a larger tuning range may be achieved for a given voltage and/or a lower voltage may be employed for a given wavelength shift to save power. Further, the higher tuning range may, for example, enable reduced reliance on a heater or other high-power circuitry for wavelength tuning, thereby also reducing power consumption.

Because of the plurality of trench structures 112, contact area between the capacitor dielectric layer 108 and the doped region 106d is increased. The increased contact area reduces contact resistance and may hence reduce RC delay of the MOSCAP 102 despite the increase in capacitance. This may, in turn, increase the speed of EO and OE signal conversions. Further, in some embodiments, the capacitor dielectric layer 108 is or comprises a high-k dielectric material. Because of the high-k dielectric material, capacitance density of the MOSCAP 102 may be further increased. This, in turn, further increases tuning efficiency.

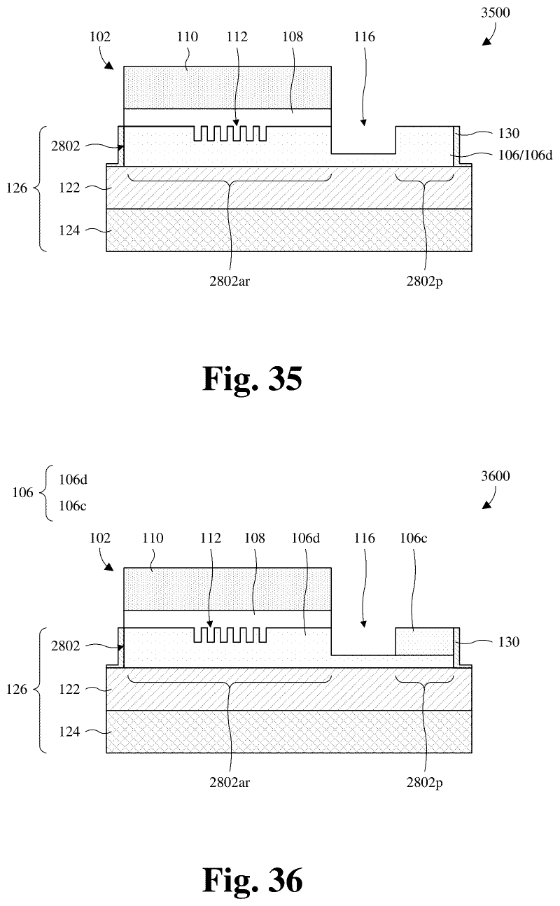

As illustrated by the view 3500 of FIG. 35, the mesa 2802 is patterned to form a trench 116 laterally separating a peripheral region 2802p of the mesa 2802 from an active region 2802ar of the mesa 2802, which accommodates the MOSCAP 102. The trench 116 extends only partially through a thickness of the mesa 2802 (which corresponds to a thickness of the semiconductor layer 106 and hence a thickness of the doped region 106d), such that the peripheral region 2802p remains electrically coupled to the active region 2802ar. The trench 116 may, for example, be formed by a photolithography/etching process or by some other suitable patterning process.

As illustrated by the view 3600 of FIG. 36, the peripheral region 2802p of the mesa 2802 is selectively doped to form a contact region 106c atop the doped region 106d. The contact region 106c has the same doping type as, but has a higher doping concentration than, the doped region 106d. Since the doped region 106d corresponds to a lower capacitor electrode of the MOSCAP 102 and extends to the contact region 106c, the contact region 106c provides low resistance coupling to the MOSCAP 102. The selective doping may, for example, be performed by ion implementation with a mask in place or by some other suitable doping process.

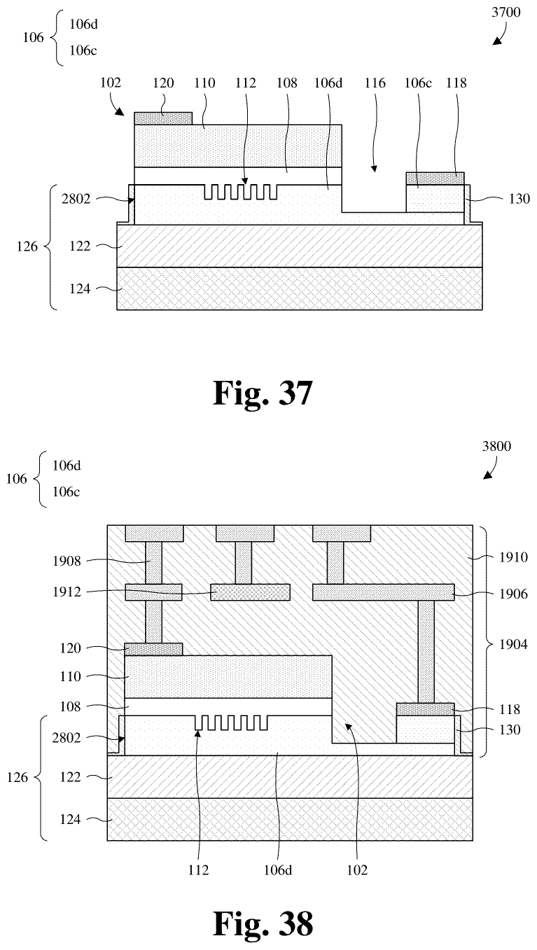

As illustrated by the view 3700 of FIG. 37, a lower conductive contact 118 and an upper conductive contact 120 are formed respectively on the contact region 106c and the upper capacitor electrode 110. In some embodiments, the lower conductive contact 118 is or comprises metal, some other suitable conductive material, or any combination of the foregoing, and/or the upper conductive contact 120 is or comprises metal, some other suitable conductive material, or any combination of the foregoing. The lower conductive contact 118 and the upper conductive contact 120 may, for example, be the same material or different materials.

In some embodiments, a process for forming the lower and upper conductive contacts 118, 120 may, for example, comprise depositing a metal-containing layer and patterning the metal-containing layer into the lower and upper conductive contacts 118, 120. In alternative embodiments, the lower and upper conductive contacts 118, 120 are formed as silicide by a salicide process. In yet other alternative embodiments, the lower and upper conductive contacts 118, 120 are formed by some other suitable process.

As illustrated by the view 3800 of FIG. 38, an interconnect structure 1904 is formed overlying and electrically coupled to the wavelength tuner formed by the MOSCAP 102. The interconnect structure 1904 comprises a plurality of wires 1906 and a plurality of vias 1908 stacked in an interconnect dielectric layer 1910. The plurality of wires 1906 are grouped into a plurality of wire levels, and the plurality of vias 1908 are grouped into a plurality of via levels alternatingly stacked with the plurality of wire levels. The various wire and via levels form conductive paths leading from the lower and upper conductive contacts 118, 120. The plurality of wires 1906 and the plurality of vias 1908 may, for example, be or comprise copper, aluminum copper, tungsten, some other suitable metal, or any combination of the foregoing.

In some embodiments, a heater 1912 is also formed overlying the MOSCAP 102 and is electrically coupled to the interconnect structure 1904. The heater 1912 may, for example, be a resistive heater or some other suitable type of heater. The heater 1912 may, for example, be employed for further wavelength tuning. Because of the high tuning efficiency of the wavelength tuner, dependence on the heater 1912 for tuning may be reduced, whereby power consumption of the heater 1912 may be reduced.

While FIGS. 27A and 27B to FIGS. 30A and 30B and FIGS. 31-38 are described with reference to a method, it will be appreciated that the structures shown in these figures are not limited to the method but rather may stand alone separate from the method. While FIGS. 27A and 27B to FIGS. 30A and 30B and FIGS. 31-38 are described as a series of acts, it will be appreciated that the order of the acts may be altered in other embodiments. While FIGS. 27A and 27B to FIGS. 30A and 30B and FIGS. 31-38 are illustrated and described as a specific set of acts, some acts that are illustrated and/or described may be omitted in other embodiments. Further, acts that are not illustrated and/or described may be included in other embodiments.

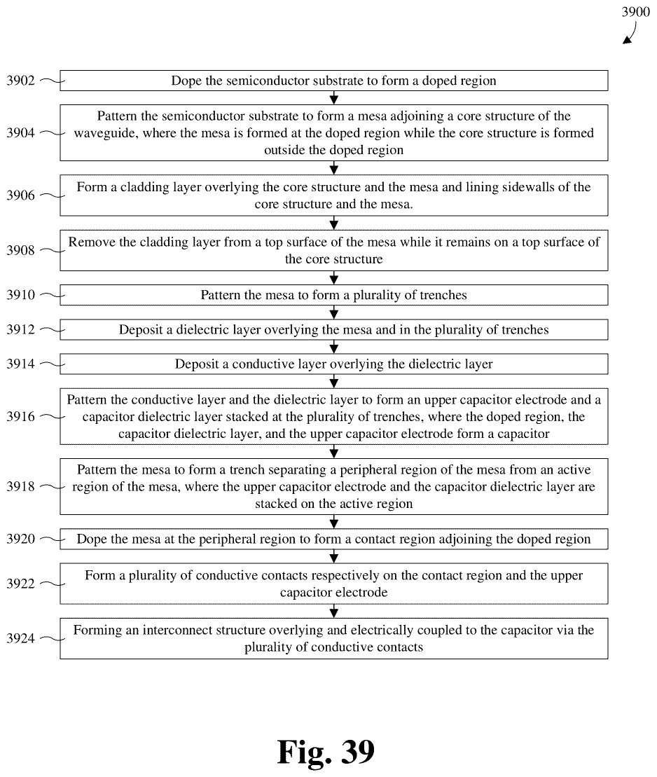

With reference to FIG. 39, a block diagram 3900 of some embodiments of the method of FIGS. 27A and 27B to FIGS. 30A and 30B and FIGS. 31-38 is provided.

At act 3902, a semiconductor substrate is doped to form a doped region. See, for example, FIGS. 27A and 27B.

At act 3904, the semiconductor substrate is patterned to form a mesa adjoining a core structure of the waveguide, where the mesa is formed at the doped region while the core structure is formed outside the doped region. See, for example, FIGS. 28A and 28B. In alternative embodiments, the core structure is formed independent of the patterning and/or is formed of a different material than the mesa. For example, the mesa may be formed of silicon, whereas the core structure may be formed of silicon nitride.

At act 3906, a cladding layer is formed overlying the core structure and the mesa and lining sidewalls of the core structure and the mesa. See, for example, FIGS. 29A and 29B.

At act 3908, the cladding layer is removed from a top surface of the mesa while it remains on a top surface of the core structure. See, for example, FIGS. 30A and 30B.

At act 3910, the mesa is patterned to form a plurality of trenches. See, for example, FIG. 31.

At act 3912, a dielectric layer is deposited overlying the mesa and in the plurality of trenches. See, for example, FIG. 32.

At act 3914, a conductive layer is deposited overlying the dielectric layer. See, for example, FIG. 33.

At act 3916, the conductive layer and the dielectric layer are patterned to form an upper capacitor electrode and a capacitor dielectric layer stacked at the plurality of trenches, where the doped region, the capacitor dielectric layer, and the upper capacitor electrode form a capacitor. See, for example, FIG. 34.

At act 3918, the mesa is patterned to form a trench separating a peripheral region of the mesa from an active region of the mesa, where the upper capacitor electrode and the capacitor dielectric layer are stacked on the active region. See, for example, FIG. 35.

At act 3920, the mesa is doped at the peripheral region to form a contact region adjoining the doped region. See, for example, FIG. 36.

At act 3922, a plurality of conductive contacts are formed respectively on the contact region and the upper capacitor electrode. See, for example, FIG. 37.

At act 3924, an interconnect structure is formed overlying and electrically coupled to the capacitor via the plurality of conductive contacts. See, for example, FIG. 38.

While the block diagram 3900 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

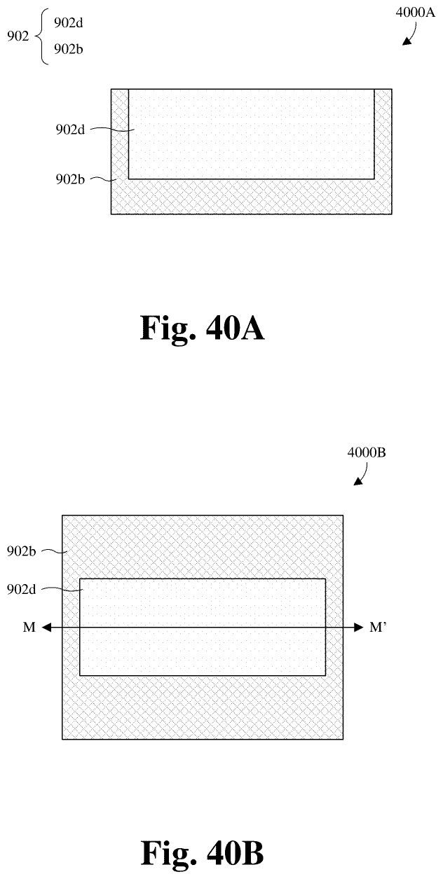

With reference to FIGS. 40A and 40B to FIGS. 46A and 46B and FIGS. 47-51, a series of views of some other embodiments of a method for forming a wavelength tuner comprising a capacitor is provided. Figures labeled with a suffix of A or with no letter suffix correspond to cross-sectional views, whereas figures labeled with a suffix of B correspond to top views for like numbered figures. Further, figures labeled with a suffix of A may, for example, be taken along line M-M′ in like numbered figures labeled with a suffix of B. The method may, for example, be employed to form the wavelength tuner in any one or combination of FIGS. 9A, 9B, 11, 12A, and 12B. Hence, the capacitor may be a MIM capacitor. Alternatively, the method may, for example, be employed to form some other suitable wavelength tuner as described above in any one or combination of FIGS. 1A through 8B and 13A through 18.

As illustrated by the views 4000A, 4000B of FIGS. 40A and 40B, a semiconductor substrate 902 is selectively doped to form a doped region 902d in the semiconductor substrate 902. The doped region 902d has an elevated doping concentration relative to a bulk region 902b of the semiconductor substrate 902, which may be undoped or lightly doped. In alternative embodiments, the selective doping may be skipped. The selective doping may, for example, be performed by ion implantation with a mask in place or by some other suitable doping process.

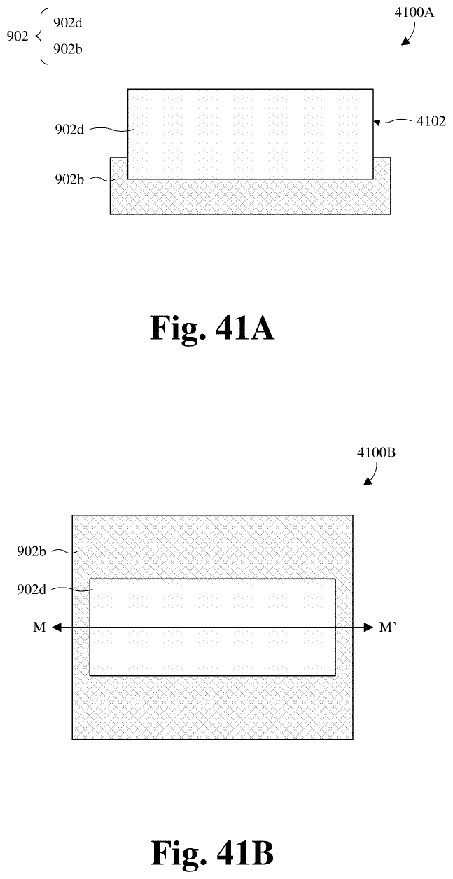

As illustrated by the views 4100A, 4100B of FIGS. 41A and 41B, the semiconductor substrate 902 is patterned to form a mesa 4102 at the doped region 106d. The patterning may, for example, be performed by a photolithography/etching process or by some other suitable patterning process. For example, a mask is formed over the semiconductor substrate 902 using photolithography, an etch is performed into the semiconductor substrate 902 with the mask in place, and then the mask is removed.

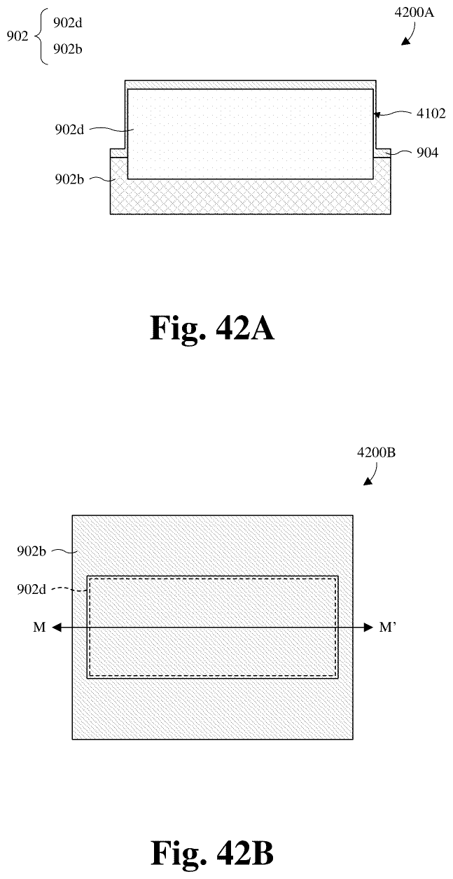

As illustrated by the views 4200A, 4200B of FIGS. 42A and 42B, a lower cladding layer 904 is deposited. The lower cladding layer 904 overlies the semiconductor substrate 902 and further lines sidewalls of the mesa 4102. The lower cladding layer 904 is deposited so it preferentially deposits on horizontal surfaces rather than vertical surfaces. Hence, the lower cladding layer 904 is thinner on sidewalls of the mesa 4102 than on upper surfaces of the semiconductor substrate 902 that extend horizontally.

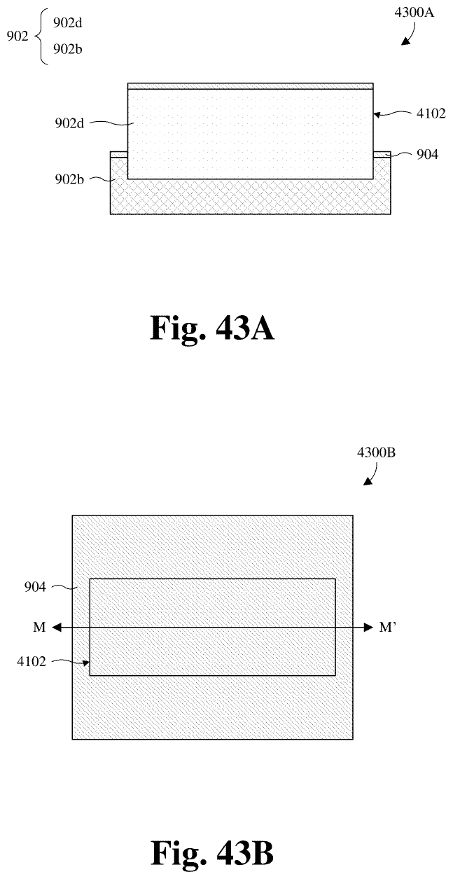

As illustrated by the views 4300A, 4300B of FIGS. 43A and 43B, the lower cladding layer 904 is removed from sidewalls of the mesa 4102. Such removal may for example, be performed by a wet etch or some other suitable isotropic etch. Because of the increased thickness on horizontally surfaces, the removal is able to fully remove the lower cladding layer 904 from sidewalls of the mesa 4102 without fully removing it from horizontally surfaces of the semiconductor substrate 902.

In alternative embodiments, the depositing and etching of FIGS. 42A and 42B to FIGS. 43A and 43B may be replaced by some other suitable processing for forming the lower cladding layer 904 on horizontally surfaces but not sidewalls of the mesa 4102. For example, the lower cladding layer 904 may be deposited fully covering the mesa 4102 and the semiconductor substrate 902, a planarization may be performed to flatten a top surface of the lower cladding layer 904, and then an etch back may be performed to recess the top surface of the lower cladding layer to below a top surface of the mesa 4102.

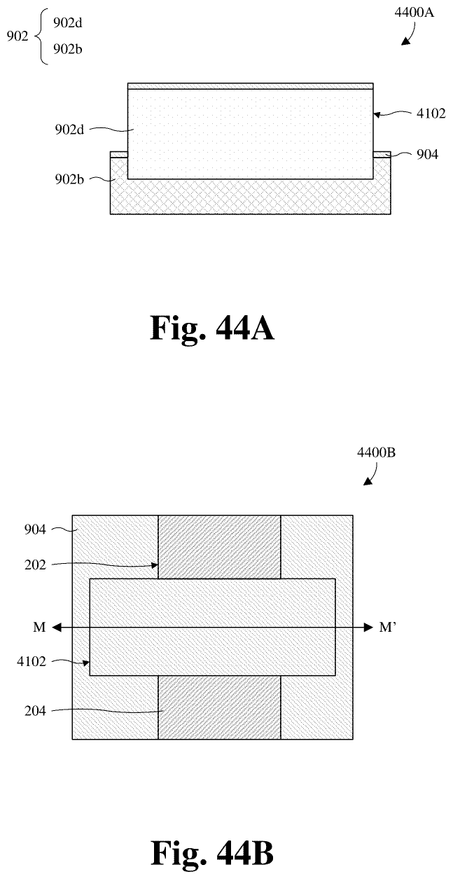

As illustrated by the views 4400A, 4400B of FIGS. 44A and 44B, a core structure 204 of a waveguide 202 is formed adjoining the mesa 4102 and overlying the lower cladding layer 904. The core structure 204 is configured to lead light through the wavelength tuner for wavelength tuning of the light. A process for forming the core structure 204 may, for example, comprise depositing a core layer overlying the lower cladding layer 904 and subsequently patterning the core layer into the core structure 204 using a photolithography/etching process. Alternatively, some other suitable process may be performed.

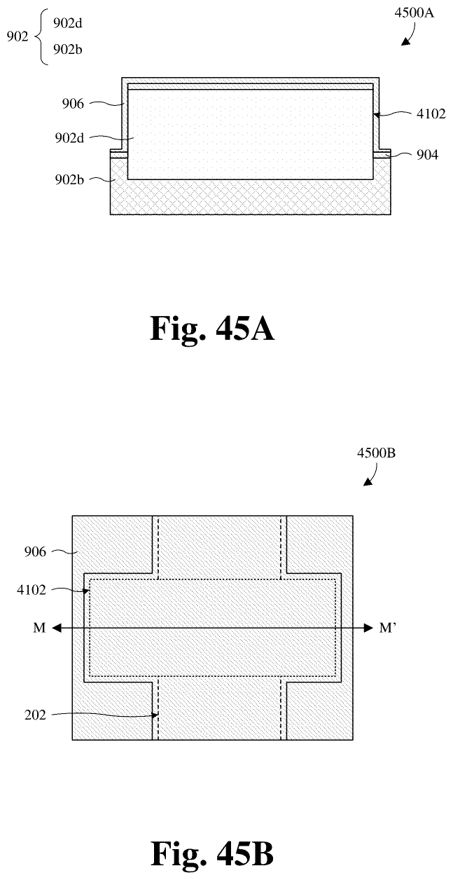

As illustrated by the views 4500A, 4500B of FIGS. 45A and 45B, an upper cladding layer 906 is deposited. The upper cladding layer 906 overlies the core structure 204 and the semiconductor substrate 902, including the mesa 4102. The upper cladding layer 906 and the lower cladding layer 904 surround the mesa 4102 and the core structure 204 of the waveguide 202 to confine light within the mesa 4102 and the core structure 204.

The lower cladding layer 904 and/or the upper cladding layer 906 may, for example, be a solid, an air gap, or some other suitable type of cladding. Further, the core structure/cladding material may, for example, be or comprise silicon/silicon oxide (e.g., Si/SiO₂), silicon nitride/silicon oxide (Si₃N₄/SiO₂), lithium niobate/silicon oxide (e.g., LiNbO₃/SiO₂), silicon/titanium oxide (e.g., Si/TiO₂), titanium oxide/silicon oxide (e.g., TiO₂/SiO₂), or the like.

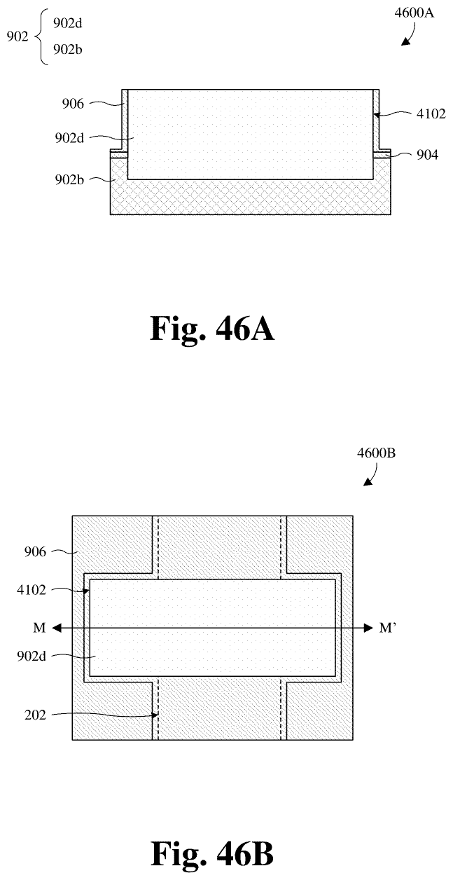

As illustrated by the views 4600A, 4600B of FIGS. 46A and 46B, the lower and upper cladding layer 904, 906 are removed from atop the mesa 4102 without removing the upper cladding layer 906 from atop the core structure 204 of the waveguide 202. Such removal may, for example, be performed by a photolithography/etching process or by some other suitable removal process. The etching may, for example, be performed by a reactive ion etch (RIE) or by some other suitable etch.

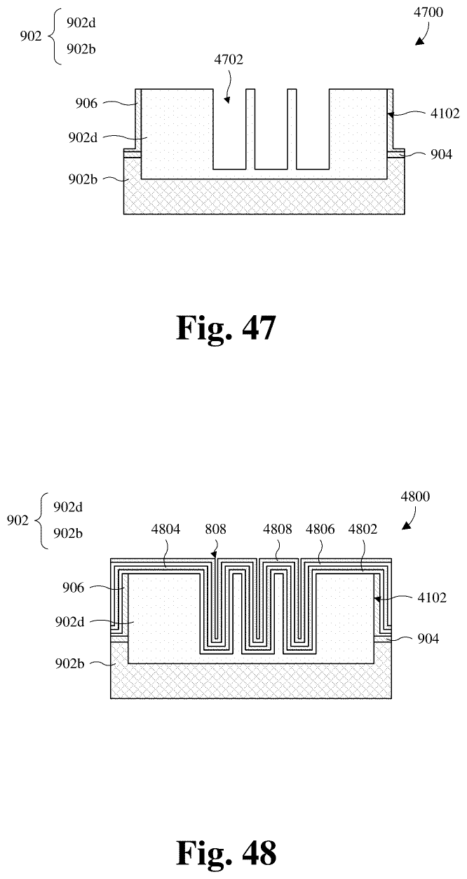

As illustrated by the view 4700 of FIG. 47, the mesa 2802 is patterned to form a plurality of trenches 4702 extending into the mesa 4102. As shown, three trenches are shown but more or less trenches are amenable. Further, different depths for the trenches are amenable. The patterning may, for example, be performed by a photolithography/etching process or by some other suitable patterning process.

As illustrated by the view 4800 of FIG. 48, a first dielectric layer 4802, a first conductive layer 4804, a second dielectric layer 4806, and a second conductive 4808 (collectively the layers or a capacitor film) are sequentially deposited stacked over the mesa 4102. Further, the layers line and partially fill the plurality of trenches 4702 of FIG. 47, such that a plurality of gaps 808 remain respectively at the plurality of trenches 4702. In alternative embodiments, the layers fully fill the plurality of trenches 4702, such that no gaps remain. Further, in alternative embodiments, the layers may include one, two, or more additional dielectric-conductive layer pairs stacked over the second conductive layer 4808, where a dielectric-conductive layer pair includes a conductive layer and an underlying dielectric layer.

The layers may, for example, be individually deposited by atomic layer deposition (ALD), chemical vapor deposition (CVD), or some other suitable deposition process. The first dielectric layer 4802 and/or the second dielectric layer 4806 may, for example, be or comprise silicon oxide, a high-k dielectric material, some other suitable dielectric material, or any combination of the foregoing. The first conductive layer 4804 and/or the second conductive layer 4808 may, for example, be or comprise metal, a metal-containing material, some other suitable conductive material, or any combination of the foregoing. The metal or metal-containing material may, for example, be or comprise titanium nitride (e.g., TiN), aluminum (e.g., Al), tantalum nitride (e.g., TaN), tungsten (e.g., W), copper (e.g., Cu), ruthenium (e.g., Ru), some other suitable conductive materials, or any combination of the foregoing.

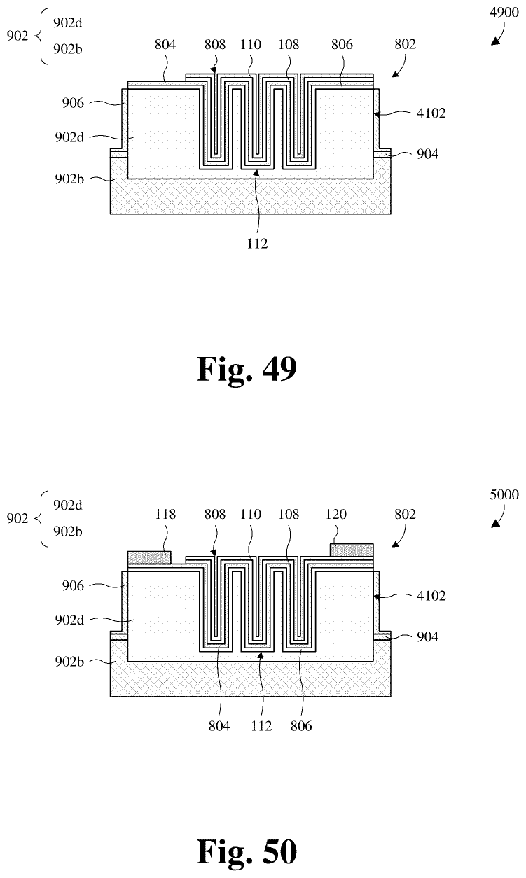

As illustrated by the view 4900 of FIG. 49, the first dielectric layer 4802, the first conductive layer 4804, the second dielectric layer 4806, and the second conductive 4808 are patterned to form a MIM capacitor 802. The MIM capacitor 802 overlies the mesa 4102 and comprises a plurality of trench structures 112 extending into the mesa 4102. Further, the MIM capacitor 802 is separated from the semiconductor substrate 902 by a buffer dielectric layer 806 formed from the first dielectric layer 4802 and comprises a lower capacitor electrode 804, a capacitor dielectric layer 108, and an upper capacitor electrode 110 formed respectively from the first conductive layer 4804, the second dielectric layer 4806, and the second conductive 4808. The patterning may, for example, be performed by a series of one or more photolithography/etching processes or by some other suitable patterning process.

During use of the wavelength tuner, a light beam is passed through the MIM capacitor 802 while the MIM capacitor 802 is biased with a voltage applied from the lower capacitor electrode 804 to the upper capacitor electrode 110. The light beam may, for example, be passed through the MIM capacitor 802 by the waveguide 202 seen in FIGS. 44A and 44B to FIGS. 46A and 46B or the like. The voltage controls an electric field along the path of the light beam, which controls a refractive index along the path. Therefore, by modulating the voltage, refractive index along the path of the light beam is modulated to wavelength tune the light beam. In some embodiments, the light beam passes through the MIM capacitor 802 in the capacitor dielectric layer 108 and/or tuning of is facilitated by the capacitor dielectric layer 108 being an electro-optic material.

As confirmed experimentally, capacitance density is proportional to tuning efficiency. Because of the plurality of trench structures 112, capacitance density of the MIM capacitor 802 is increased at the light beam and hence tuning efficiency (e.g., wavelength shift per unit voltage) is increased. Because of the plurality of trench structures 112, contact area between the capacitor dielectric layer 108 and the doped region 106d is increased. The increased contact area reduces contact resistance and may hence reduce RC delay of the MIM capacitor 802 despite the increase in capacitance. Because of the high-k dielectric material, capacitance density of the MIM capacitor 802 may be further increased. This, in turn, further increases tuning efficiency.

As illustrated by the view 5000 of FIG. 50, a lower conductive contact 118 and an upper conductive contact 120 are formed respectively on the lower capacitor electrode 804 and the upper capacitor electrode 110. In some embodiments, the lower conductive contact 118 and/or the upper conductive contact 120 is/are as described with regard to FIG. 37.

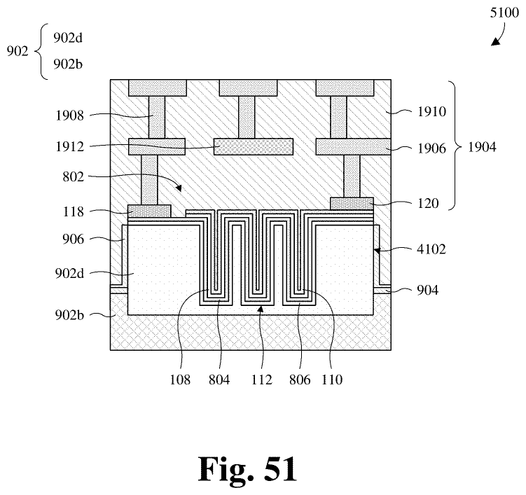

As illustrated by the view 5100 of FIG. 51, an interconnect structure 1904 is formed overlying and electrically coupled to the wavelength tuner formed by the MIM capacitor 802. The interconnect structure 1904 comprises a plurality of wires 1906 and a plurality of vias 1908 stacked in an interconnect dielectric layer 1910. In some embodiments, the interconnect structure 1904 is as described with regard to FIG. 38.

While FIGS. 40A and 40B to FIGS. 46A and 46B and FIGS. 47-51 are described with reference to a method, it will be appreciated that the structures shown in these figures are not limited to the method but rather may stand alone separate from the method. While FIGS. 40A and 40B to FIGS. 46A and 46B and FIGS. 47-51 are described as a series of acts, it will be appreciated that the order of the acts may be altered in other embodiments. While FIGS. 40A and 40B to FIGS. 46A and 46B and FIGS. 47-51 are illustrated and described as a specific set of acts, some acts that are illustrated and/or described may be omitted in other embodiments. Further, acts that are not illustrated and/or described may be included in other embodiments.

In some embodiments, the present disclosure provides a method, including: forming a waveguide on a substrate; patterning the substrate to form a trench, wherein the waveguide leads to the trench; depositing a dielectric layer overlying the substrate and in the trench; depositing a conductive layer overlying the dielectric layer; and patterning the conductive layer and the dielectric layer to form a capacitor with a trench structure in the trench. In some embodiments, the trench is formed in a semiconductor portion of the substrate having a first doping type, wherein the conductive layer includes a semiconductor having a second doping type opposite the first doping type. In some embodiments, the method further includes planarizing a top surface of the dielectric layer before the depositing of the conductive layer. In some embodiments, the method further includes depositing an additional conductive layer overlying the substrate and lining the trench before the dielectric layer is deposited, wherein the additional conductive layer is patterned with the conductive layer and the dielectric layer to form the capacitor, and wherein the conductive layer and the additional conductive layer include metal. In some embodiments, the substrate corresponds to a silicon-on-insulator substrate and includes a handle substrate, an insulator layer over the handle substrate, and a semiconductor layer over the insulator layer, wherein the trench is formed in the semiconductor layer and spaced from the insulator layer. In some embodiments, the method further includes: patterning the substrate to demarcate a semiconductor mesa, wherein the trench is formed in the semiconductor mesa; and after the patterning to form the capacitor, patterning the semiconductor mesa to demarcate an active region of the semiconductor mesa and a peripheral region of the semiconductor mesa, wherein the capacitor is formed at the active region. In some embodiments, the method further includes: doping the peripheral region of the semiconductor mesa to form a contact region electrically coupled to the capacitor; and forming a pair of conductive contacts respectively on the contact region and the conductive layer.

In some embodiments, the present disclosure provides another method, including: forming a waveguide on a substrate; forming a dielectric layer overlying the substrate, wherein the dielectric layer has a plurality of protrusions extending vertically; depositing a conductive layer overlying the dielectric layer; and performing an etch into the conductive layer and the dielectric layer to form a capacitor, which includes the plurality of protrusions and which is configured to modulate a wavelength of an optical signal carried by the waveguide. In some embodiments, the method further includes forming a bus waveguide bordering the waveguide, wherein the waveguide and the capacitor collectively have a ring-shaped top geometry. In some embodiments, the method further includes: forming an additional waveguide on the substrate; forming an optical splitter having two outputs respectively coupled to the additional waveguide and a first segment of the waveguide; and forming an optical combiner having two inputs respectively coupled to the additional waveguide and a second segment of the waveguide, wherein the capacitor is between and borders the first segment of the waveguide and the second segment of the waveguide. In some embodiments, the substrate corresponds to a semiconductor-on-insulator (SOI) substrate and the method further includes performing an additional etch into a device layer of the SOI substrate to thin a region of the device layer between the capacitor and a contact region of the device layer, wherein the capacitor is electrically coupled to the contact region via the region after the additional etch. In some embodiments, the method further includes forming an interconnect structure overlying and electrically coupled to the capacitor. In some embodiments, the method further includes forming a heater overlying the capacitor. In some embodiments, the method further includes: performing a first additional etch into the substrate to form the waveguide and a mesa, wherein the waveguide and the mesa include semiconductor material; and performing a second additional etch into the mesa to form a plurality of trenches within which the plurality of protrusions of the dielectric layer are respectively formed.

In some embodiments, the present disclosure provides a semiconductor structure, including: a capacitor on a substrate and including: a first electrode overlying the substrate; and a dielectric layer between the substrate and the first electrode, wherein the dielectric layer at least partially forms a plurality of trench structures extending into the substrate and/or into the first electrode; and a waveguide on the substrate and extending to the plurality of trench structures. In some embodiments, the plurality of trench structures extend into a semiconductor portion of the substrate, which is doped and forms a second electrode of the capacitor, wherein the first electrode includes a doped semiconductor having an opposite doping type as the semiconductor portion of the substrate. In some embodiments, the dielectric layer includes a high-k dielectric material. In some embodiments, a top surface of the dielectric layer is substantially planar and continuous along an entire width of the capacitor. In some embodiments, the capacitor includes a second electrode between the dielectric layer and the substrate, wherein the second electrode includes metal and partially forms the plurality of trench structures. In some embodiments, the waveguide has a ring-shaped top geometry and, together with the capacitor, forms a MRM.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a waveguide on a substrate;
patterning the substrate to form a trench, wherein the waveguide leads to the trench;
depositing a dielectric layer overlying the substrate and in the trench;
depositing a conductive layer overlying the dielectric layer; and
patterning the conductive layer and the dielectric layer to form a capacitor with a trench structure in the trench.

2. The method according to claim 1, wherein the trench is formed in a semiconductor portion of the substrate having a first doping type, and wherein the conductive layer comprises a semiconductor having a second doping type opposite the first doping type.

3. The method according to claim 1, further comprising:
planarizing a top surface of the dielectric layer before the depositing of the conductive layer.

4. The method according to claim 1, further comprising:
depositing an additional conductive layer overlying the substrate and lining the trench before the dielectric layer is deposited, wherein the additional conductive layer is patterned with the conductive layer and the dielectric layer to form the capacitor, and wherein the conductive layer and the additional conductive layer comprise metal.

5. The method according to claim 1, wherein the substrate corresponds to a silicon-on-insulator substrate and comprises a handle substrate, an insulator layer over the handle substrate, and a semiconductor layer over the insulator layer, and wherein the trench is formed in the semiconductor layer and spaced from the insulator layer.

6. The method according to claim 1, further comprising:
patterning the substrate to demarcate a semiconductor mesa, wherein the trench is formed in the semiconductor mesa; and
after the patterning to form the capacitor, patterning the semiconductor mesa to demarcate an active region of the semiconductor mesa and a peripheral region of the semiconductor mesa, wherein the capacitor is formed at the active region.

7. The method according to claim 6, further comprising:
doping the peripheral region of the semiconductor mesa to form a contact region electrically coupled to the capacitor; and
forming a pair of conductive contacts respectively on the contact region and the conductive layer.

8. A method, comprising:
forming a waveguide on a substrate;
forming a dielectric layer overlying the substrate, wherein the dielectric layer has a plurality of protrusions extending vertically;
depositing a conductive layer overlying the dielectric layer; and
performing an etch into the conductive layer and the dielectric layer to form a capacitor, which comprises the plurality of protrusions and which is configured to modulate a wavelength of an optical signal carried by the waveguide.

9. The method according to claim 8, wherein the method further comprises:
forming a bus waveguide bordering the waveguide, wherein the waveguide and the capacitor collectively have a ring-shaped top geometry.

10. The method according to claim 8, further comprising:
forming an additional waveguide on the substrate;
forming an optical splitter having two outputs respectively coupled to the additional waveguide and a first segment of the waveguide; and
forming an optical combiner having two inputs respectively coupled to the additional waveguide and a second segment of the waveguide, wherein the capacitor is between and borders the first segment of the waveguide and the second segment of the waveguide.

11. The method according to claim 8, wherein the substrate corresponds to a semiconductor-on-insulator (SOI) substrate and the method further comprises:
performing an additional etch into a device layer of the SOI substrate to thin a region of the device layer between the capacitor and a contact region of the device layer, wherein the capacitor is electrically coupled to the contact region via the region after the additional etch.

12. The method according to claim 8, further comprising:
forming an interconnect structure overlying and electrically coupled to the capacitor.

13. The method according to claim 8, further comprising:
forming a heater overlying the capacitor.

14. The method according to claim 8, further comprising:
performing a first additional etch into the substrate to form the waveguide and a mesa, wherein the waveguide and the mesa comprise semiconductor material; and
performing a second additional etch into the mesa to form a plurality of trenches within which the plurality of protrusions of the dielectric layer are respectively formed.

15. A semiconductor structure, comprising:
a capacitor on a substrate and comprising:
a first electrode overlying the substrate; and
a dielectric layer between the substrate and the first electrode, wherein the dielectric layer at least partially forms a plurality of trench structures extending into the substrate and/or into the first electrode; and
a waveguide on the substrate and extending to the capacitor.

16. The semiconductor structure according to claim 15, wherein the plurality of trench structures extend into a semiconductor portion of the substrate, which is doped and forms a second electrode of the capacitor, and wherein the first electrode comprises a doped semiconductor having an opposite doping type as the semiconductor portion of the substrate.

17. The semiconductor structure according to claim 15, wherein the dielectric layer comprises a high-k dielectric material.

18. The semiconductor structure according to claim 15, wherein a top surface of the dielectric layer is substantially planar and continuous along an entire width of the capacitor.

19. The semiconductor structure according to claim 15, wherein the capacitor comprises a second electrode between the dielectric layer and the substrate, and wherein the second electrode comprises metal and partially forms the plurality of trench structures.

20. The semiconductor structure according to claim 15, wherein the waveguide has a ring-shaped top geometry and, together with the capacitor, forms a microring modulator (MRM).
